(19) United States
(12) Patent Application Publication
(10) Pub. No.: US 2013/0101731 A1
(43) Pub. Date: Apr. 25, 2013

(54) METHOD OF MANUFACTURING PIEZOELECTRIC ELEMENT, METHOD OF MANUFACTURING LIQUID EJECTION HEAD, AND METHOD OF MANUFACTURING LIQUID EJECTING APPARATUS

(71) Applicant: Seiko Epson Corporation, Tokyo (JP)

(72) Inventors: Takayuki YONEMURA, Suwa (JP); Yasuhiro ITAYAMA, Chino (JP)

(73) Assignee: Seiko Epson Corporation, Tokyo (JP)

(21) Appl. No.: 13/654,650

(22) Filed: Oct. 18, 2012

(30) Foreign Application Priority Data
Oct. 20, 2011 (JP) 2011-230643
Feb. 28, 2012 (JP) 2012-041034

(51) Int. Cl. H01L 41/22

(52) U.S. Cl. 427/100

(57) ABSTRACT

A method of manufacturing a piezoelectric element includes a process of forming on the surface of an electrode having lanthanum nickel preferentially aligned in (100) plane, at least on a surface thereof; a process of applying a precursor solution including at least Bi, Ba, Fe, and Ti onto the surface of the electrode, and a process of crystallizing the applied precursor solution to form the piezoelectric layer including a perovskite oxide preferentially aligned in (100) plane.

The entire disclosure of Japanese Patent Application Nos. 2011-230643, filed Oct. 20, 2011, and 2012-041034, filed Feb. 28, 2012, are expressly incorporated by reference herein.

### BACKGROUND

1. Technical Field

The present invention relates to a method of manufacturing a piezoelectric element, a method of manufacturing a liquid ejecting head, and a method of manufacturing a liquid ejecting apparatus.

2. Related Art

In a liquid ejecting apparatus such as an ink jet printer, a liquid ejecting head provided with a piezoelectric element is used. For example, the piezoelectric element includes a lower electrode such as Pt (platinum) provided on a surface of a vibration plate constituting a part of a wall face of a pressure generation chamber, a piezoelectric thin film provided on the lower electrode, and an upper electrode provided on the piezoelectric thin film. When the piezoelectric thin film is formed by a liquid phase method such as a spin coating method, the piezoelectric thin film is formed by applying a precursor solution onto the lower electrode and crystallizing the application film. In the liquid phase method represented by the spin coating method, a piezoelectric thin film may be formed under the atmosphere, and the piezoelectric thin film may have a large area.

Since PZT (lead zirconate titanate, Pb (Zrₓ, Ti₁₋ₓ) O₃) used in the piezoelectric thin film includes lead (Pb), non-lead-based piezoelectric materials which do not include lead have been researched and developed from the viewpoint of environmental load. In JP-A-2009-242229, manufacturing a non-lead-based piezoelectric material of a (Ba, Bi)(Ti, Fe, Mn) O₃ film by a vapor deposition method such as pulse laser deposition (PLD) is proposed.

Generally, in the vapor deposition method, a high vacuum is necessary, and thus it is difficult to avoid a large size and a high cost of an apparatus. In addition, it is difficult to secure in-plane uniformity of the piezoelectric thin film, and to have a large area.

However, a non-lead-based piezoelectric thin film including Bi (bismuth), Ba (barium), Fe (iron), and Ti (titanium) by a liquid phase method is formed to manufacture a piezoelectric element, but it is found that there is a case where cracks occur in the piezoelectric thin film differently from the PZT. In addition, when the piezoelectric thin film is kept in humid air, it is found that there is a case where an insulating breakdown voltage is decreased. In addition, such a problem is not limited to a liquid ejecting head, and is present even in a piezoelectric element such as a piezoelectric actuator and sensor in the same manner.

### SUMMARY

An advantage of some aspects of the invention is to improve performance of a piezoelectric element provided with a piezoelectric layer including at least Bi, Ba, Fe, and Ti by a liquid phase method, a liquid ejecting head, and a liquid ejecting apparatus.

According to an aspect of the invention, there is provided a method of manufacturing a piezoelectric element having a piezoelectric layer and an electrode, the method including: forming the electrode having at least lanthanum nickel preferentially aligned in (100) plane, on a surface thereof; applying a precursor solution including at least Bi, Ba, Fe, and Ti onto the surface of the electrode; and crystallizing the applied precursor solution to form the piezoelectric layer including a perovskite oxide preferentially aligned in (100) plane.

According to another aspect of the invention, there is provided a method of manufacturing a liquid ejecting head including the method of manufacturing the piezoelectric element.

According to still another aspect of the invention, there is provided a method of manufacturing a liquid ejecting apparatus including the method of manufacturing the liquid ejecting head.

When the precursor solution including at least Bi, Ba, Fe, and Ti is applied onto the surface of the electrode without lanthanum nickel and is crystallized, the piezoelectric layer including a perovskite oxide preferentially aligned in (110) plane is formed. In the manufacturing method of the invention, lanthanum nickel preferentially aligned in (100) plane is provided at least on the electrode surface. For this reason, when the precursor solution including at least Bi, Ba, Fe, and Ti is applied and crystallized, it is thought that it is possible to form the piezoelectric layer including the perovskite oxide preferentially aligned in (100) plane. In the piezoelectric element formed by the manufacturing method, it is found that occurrence of cracks in the piezoelectric layer is suppressed, and humidity resistance is improved.

In the electrode, the lanthanum nickel preferentially aligned in (100) plane may be provided at least on the surface, may include platinum, gold, iridium, titanium oxide, and the like, and may include impurities.

The precursor solution includes a state such as sol. The precursor solution may include metals other than Bi, Ba, Fe, and Ti, such as Mn (manganese), and may include impurities. Obviously, the metals included in the precursor solution may include an ionic state. The piezoelectric layer may also include metals other than Bi, Ba, Fe, and Ti, such as Mn, and may include impurities.

In the method of manufacturing a piezoelectric element according to the aspect of the invention, the forming of the piezoelectric layer may include first process of the application film on the surface of the electrode to lower than a crystallization temperature of the perovskite oxide, and second heating of the application film on the surface of the electrode after the first heating at a temperature equal to or higher than the crystallization temperature. By such heating, in the aspect, it is possible to satisfactorily form the piezoelectric layer.

In the method of manufacturing a piezoelectric element according to the aspect of the invention, the crystallization temperature may be 400 to 450° C. In the second heating, the application film on the surface of the electrode may be heated equal to or higher than 450° C., and the application film on the surface of the electrode may be heated equal to or higher than the crystallization temperature by an infrared lamp annealing device. Even in such an aspect, it is possible to satisfactorily form the piezoelectric layer.

When the precursor solution includes Mn, it is expected that an insulating property of the piezoelectric layer will be improved by becoming high (improvement of leak characteristics).

When a factor F*₍₁₀₀₎ of the piezoelectric layer is equal to or more than 0.89, where a reflection intensity from a (100) alignment plane acquired from an X-ray diffraction chart of the piezoelectric layer according to an X-ray diffraction wide angle method is A₍₁₀₀₎, a reflection intensity from a (110) alignment plane acquired from the X-ray diffraction chart is A₍₁₁₀₎, A₍₁₀₀₎/(A₍₁₀₀₎+A₍₁₁₀₎) is P*₍₁₀₀₎, a reflection intensity from the (100) alignment plane when crystals are not aligned is A₀₍₁₀₀₎, a reflection intensity from the (110) alignment plane when crystals are not aligned is A₀₍₁₁₀₎, A₀₍₁₀₀₎/(A₀₍₁₀₀₎+A₀₍₁₁₀₎) is P*₀₍₁₀₀₎, and (P*₍₁₀₀₎−P*₀₍₁₀₀₎)/(1−P*₀₍₁₀₀₎) is a factor F*₍₁₀₀₎, it is possible to provide a preferable piezoelectric element in which occurrence of cracks in the piezoelectric layer is suppressed.

### BRIEF DESCRIPTION OF THE DRAWINGS

The invention will be described with reference to the accompanying drawings, wherein like numbers reference like elements.

FIG. 1A is a cross-sectional view of a liquid ejecting head for describing an example of a manufacturing method, and FIG. 1B is a flowchart illustrating an example of a process of manufacturing a piezoelectric element.

FIG. 2 is an exploded perspective view for convenience illustrating an example of a schematic configuration of a recording head.

FIG. 3A to FIG. 3C are cross-sectional views illustrating an example of a process of manufacturing a recording head.

FIG. 4A to FIG. 4C are cross-sectional views illustrating an example of a process of manufacturing a recording head.

FIG. 5 is a diagram illustrating an example of a schematic configuration of a recording apparatus.

FIG. 6A is a diagram illustrating a TG-DTA measurement result of solution 2 in Test Example 1, and FIG. 6B is a diagram illustrating a crystallization temperature.

FIG. 7A is a diagram illustrating an X-ray diffraction chart based on XRD in Test Example 2, and FIG. 7B is a diagram illustrating a calculation result of factors F*₍₁₀₀₎ and F*₍₁₁₀₎.

FIG. 8 is a diagram obtained by taking a photograph of a fracture cross-section of a sample in which a thin film is formed on a substrate, using an SEM.

FIG. 9 is a diagram obtained by taking a photograph of a fracture cross-section of a sample in which a comparative thin film is formed on a substrate, using an SEM.

FIG. 10 is a dark-field image illustrating a surface of a sample in which a thin film is formed on a substrate.

FIG. 11 is a dark-field image illustrating a surface of a sample in which a comparative thin film is formed on a substrate.

FIG. 12A and FIG. 12B are graphs illustrating a relationship of current density (logarithm)-voltage between an element and a comparative element.

FIG. 13A and FIG. 13B are graphs illustrating hysteresis characteristics of an element sample.

FIG. 14 is a graph illustrating hysteresis characteristics of an element.

FIG. 15A and FIG. 15B are graphs illustrating hysteresis characteristics of a comparative element sample.

FIG. 16 is a graph illustrating a relationship between electric-field-induced strain and voltage of an element.

FIG. 17 is a diagram illustrating a burning temperature, a factor F*₍₁₀₀₎, and an external appearance of thin films.

FIG. 18A and FIG. 18B are diagrams illustrating a result of analyzing an La distribution of a piezoelectric thin film by a SIMS (secondary ion mass spectrometry) device.

FIG. 19A and FIG. 19B are diagrams illustrating a result of analyzing an La distribution of a piezoelectric thin film by SIMS.

### DESCRIPTION OF EXEMPLARY EMBODIMENTS

Hereinafter, embodiments of the invention will be described. Of course, the embodiments described as follows are merely examples of the invention.

### 1. SUMMARY OF METHODS OF MANUFACTURING PIEZOELECTRIC ELEMENT, LIQUID EJECTING HEAD, AND LIQUID EJECTING APPARATUS

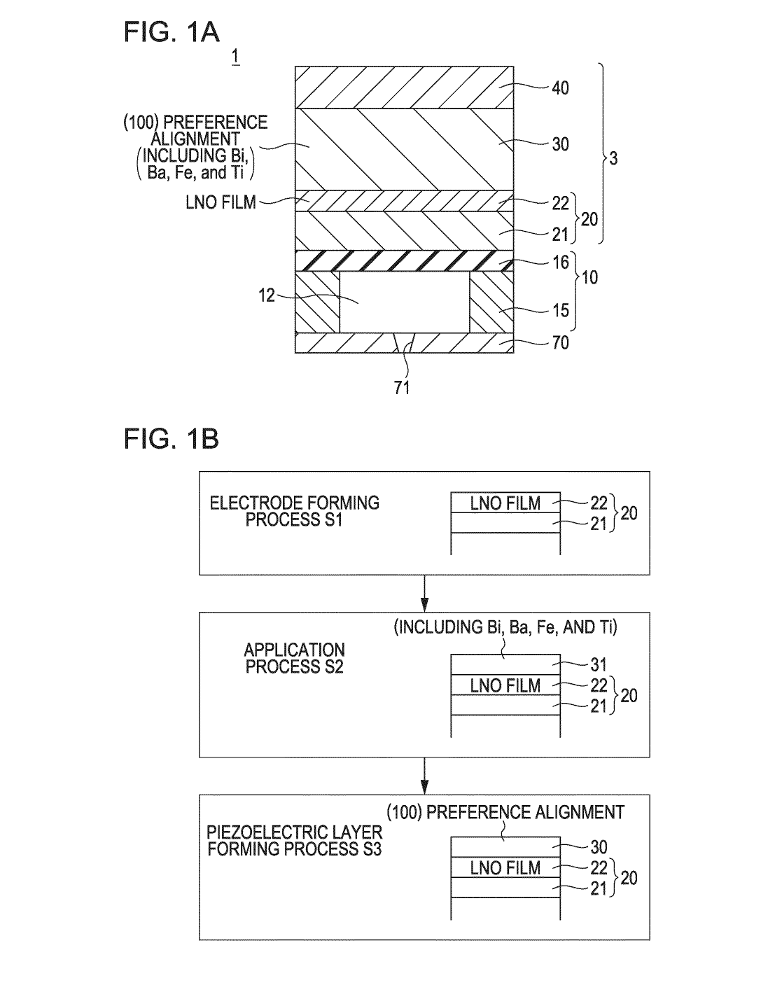

First, examples of the manufacturing methods will be described with reference to FIG. 1A and FIG. 1B. A recording head (a liquid ejecting head) 1 exemplified in FIG. 1A is provided with a piezoelectric element 3 having a piezoelectric layer 30 and electrodes 20 and 40, and a pressure generation chamber 12 which communicates with a nozzle passage 71 and in which pressure is changed by the piezoelectric element 3. Accordingly, the method of manufacturing a liquid ejecting head includes a process of forming the piezoelectric element, and a process of forming the pressure generation chamber. The pressure generation chamber 12 is formed on a silicon substrate 15 of a flow path formation substrate 10. The nozzle passage 71 is formed in a nozzle plate 70. The lower electrode (the first electrode) 20, the piezoelectric layer 30, and the upper electrode (the second electrode) 40 are laminated on an elastic film (a vibration plate) 16 of the flow path formation substrate 10 in this order, and the nozzle plate 70 is fixed to the silicon substrate 15 provided with the pressure generation chamber 12.

The positional relationship described in the specification is merely an example for describing the invention, and does not limit the invention. Accordingly, the invention includes a case where the second electrode is disposed at a position other than above the first electrode, for example, down, left, right, and the like.

The manufacturing method exemplified in FIG. 1B includes processes S1 to S3.

In the electrode formation process S1, an electrode 20 having lanthanum nickel preferentially aligned in (100) plane at least on the surface thereof is formed. The preferential alignment in (100) plane means that a Lotgering factor F₍₁₀₀₎ or a factor F*₍₁₀₀₎ to be described later is equal to or more than a predetermined value (for example, 0.5). The lanthanum nickel is represented by a chemical formula LaNiO_{y}. It is standard that y is 3, but it may deviate from 3 within the range preferentially aligned in (100) plane. The electrode 20 may be a conductive layer in which a LNO (lanthanum nickel) film 22 is formed on a surface of a conductive film 21 with platinum, gold, iridium, titanium oxide, a combination thereof, and the like, and may be an LNO film. The LNO film has a property of preferential alignment in a (100) face. The LNO film 22 may include lanthanum nickel as a main component, and the other materials (for example, metals) with a low molecular ratio. Accordingly, the surface of the electrode 20 may include a material other than lanthanum nickel. The main component is a component with the highest molecular ratio in included components.

In the application process S2, a precursor solution 31 including at least Bi, Ba, Fe, and Ti is applied at least onto the surface of the electrode 20. The precursor solution may include Bi, Ba, Fe, and Ti as main components, and the other metals (for example, Mn) with a low molecular ratio. Herein, the main components are one or more target components in which a sum of molecular ratios is higher than a molecular ratio of the other contained components. The application of the precursor solution may be performed by a liquid phase method such as a spin coating method, a dip coating method, and an ink jet method.

In the piezoelectric layer formation process S3, the applied precursor solution 31 is crystallized to form the piezoelectric layer 30 including a perovskite oxide preferentially aligned in (100) plane. The obtained perovskite oxide includes at least Bi, Ba, Fe, and Ti, and may include Bi, Ba, Fe, and Ti as main components, and the other metals (for example, Mn) with a low molecular ratio. The piezoelectric layer 30 may include a material (for example, a metal oxide) other than the perovskite oxide.

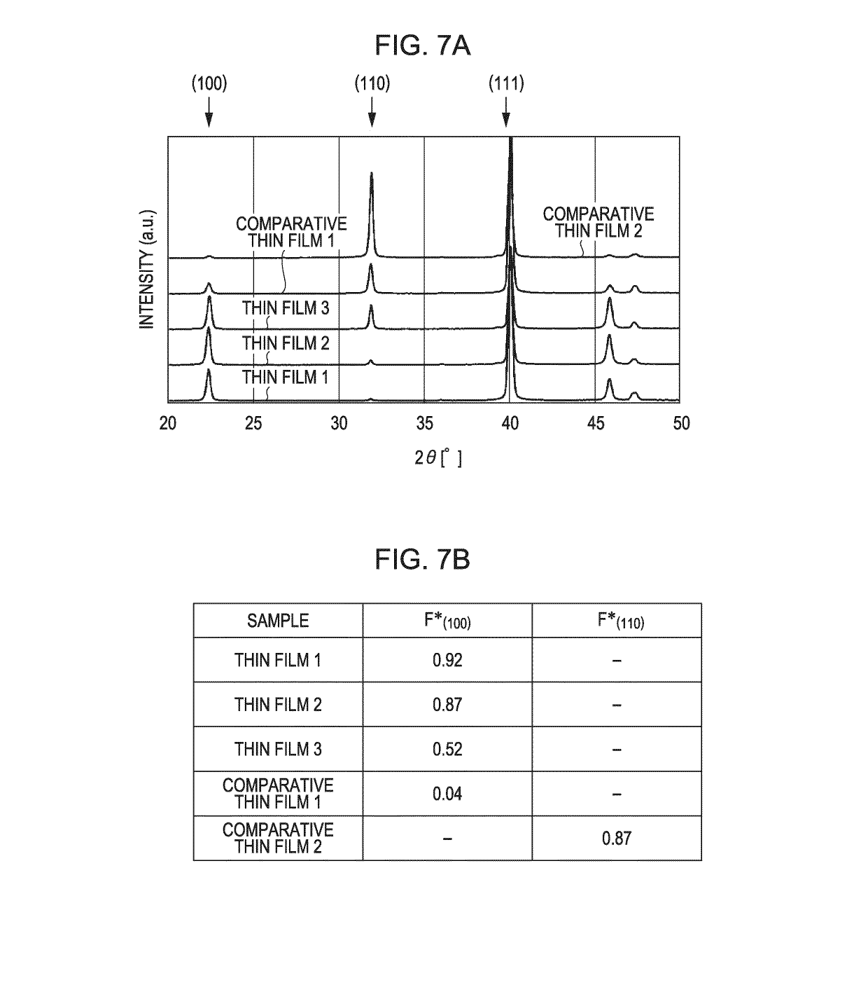

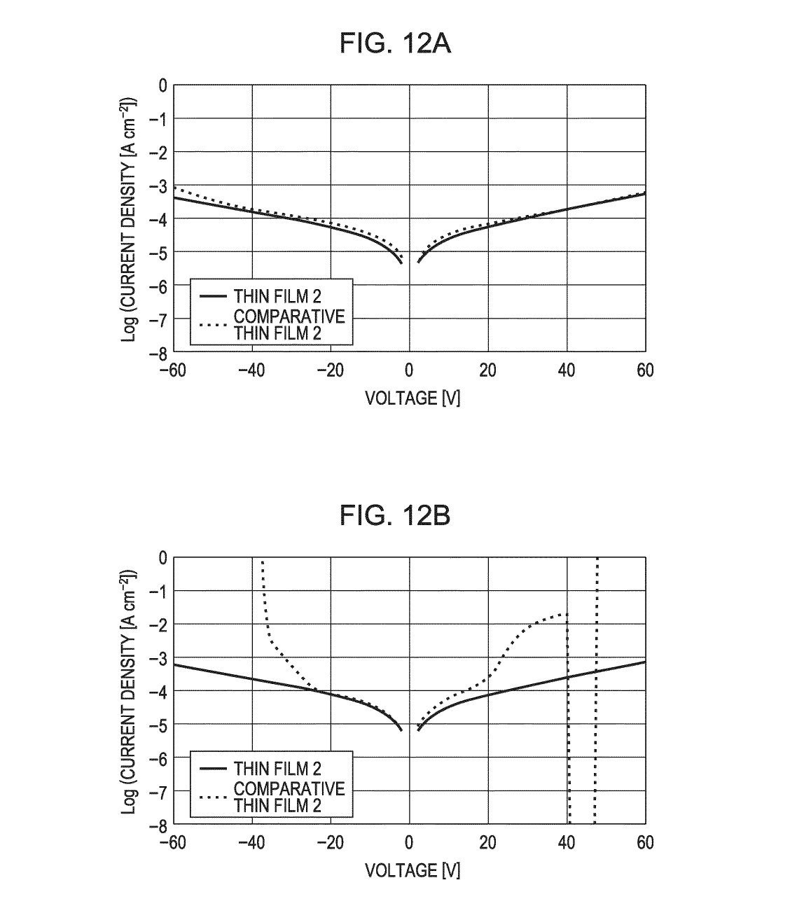

As exemplified in F*₍₁₁₀₎ of a comparative thin film 2 in FIG. 7B, when a non-lead precursor solution including Bi, Ba, Fe, and Ti is applied onto the surface of the electrode without LNO and is crystallized, the piezoelectric layer including the perovskite oxide preferentially aligned in (110) plane is formed. In such a piezoelectric layer, cracks may occur as exemplified in a dark-field image in FIG. 11. In addition, when the piezoelectric element having such a piezoelectric layer is kept in humid air, as exemplified in a relationship of current density-voltage of the comparative thin film 2 in FIG. 12A and FIG. 12B, an insulating breakdown voltage of the piezoelectric layer, that is, a rapid leak current occurrence voltage may be decreased as compared with a condition under dry air.

In the manufacturing method, the precursor solution including at least Bi, Ba, Fe, and Ti is applied onto the LNO film preferentially aligned in (100) plane and is crystallized. Accordingly, it is thought that it is possible to form the piezoelectric layer 30 including the perovskite oxide preferentially aligned in (100) plane. The piezoelectric layer 30 may include such a perovskite oxide, and may include the perovskite oxide as a main component, and the other materials (for example, a metal oxide) with a low molecular ratio.

The metals included in the precursor solution are disposed at sites according to an atomic radius in the perovskite structure. The obtained perovskite oxide includes at least Bi and Ba in an A site, and includes at least Fe and Ti in a B site. Such a perovskite oxide includes a non-lead-based perovskite oxide with a composition represented by the following general formulas.

(Bi,Ba)(Fe,Ti)O_{z} (1)

(Bi,Ba,MA)(Fe,Ti)O_{z} (2)

(Bi,Ba)(Fe,Ti,MB)O_{z} (3)

(Bi,Ba,MA)(Fe,Ti,MB)O_{z} (4)

Herein, MA is one or more kinds of metal elements except for Bi, Ba, and Pb, and MB is one or more kinds of metal elements except for Fe, Ti, and Pb. It is standard that z is 3, but it may deviate from 3 within a range where it is possible to take the perovskite structure. It is standard that a ratio between the A site element and the B site element is 1:1, but may it deviate from 1:1 within a range in which it is possible to adopt the perovskite structure.

A molecular number ratio of Bi with respect to a molecular number sum of Bi, Ba, and MA may be, for example, about 50 to 99.9%. A molecular number ratio of Ba with respect to a molecular number sum of Bi, Ba, and MA may be, for example, about 0.1 to 50%. A molecular number ratio of MA with respect to a molecular number sum of Bi, Ba, and MA may be, for example, about 0.1 to 33%.

A molecular number ratio of Fe with respect to a molecular number sum of Fe, Ti, and MB may be, for example, about 50 to 99.9%. A molecular number ratio of Ti with respect to a molecular number sum of Fe, Ti, and MB may be, for example, about 0.1 to 50%. A molecular number ratio of MB with respect to a molecular number sum of Fe, Ti, and MB may be, for example, about 0.1 to 33%.

The MB elements addable to the precursor solution include Mn and the like. A molecular concentration ratio of Mn in the B site constituent metal may be, for example, 0.1 to 10%, where the whole molecular concentration ratio of the B site constituent metal is 100%. When Mn is added, an effect of improving an insulating property of the piezoelectric layer by becoming high (improving leak characteristics) is expected. However, even when there is no Mn, it is possible to form the piezoelectric element having a piezoelectric performance.

A crystallization temperature of the piezoelectric layer 30 having the perovskite oxide including at least Bi, Ba, Fe, and Ti is normally 400 to 450° C.

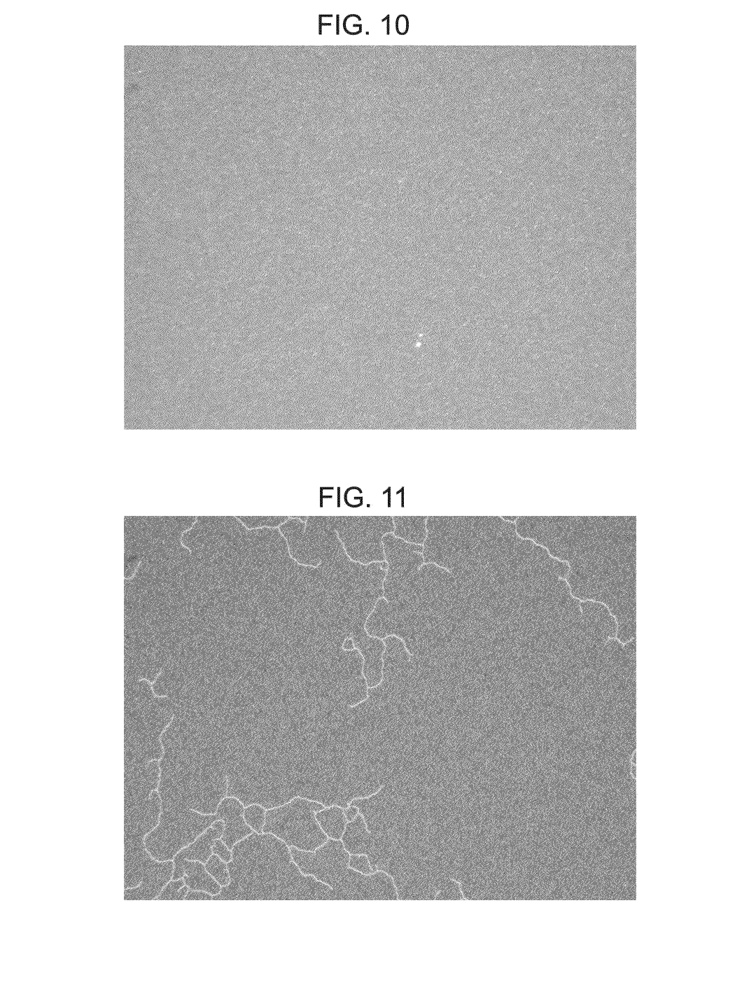

In the piezoelectric layer 30 including the perovskite oxide preferentially aligned in (100) plane, as exemplified in the dark-field image in FIG. 10, it was found that occurrence of cracks is supplied. Even when the piezoelectric element having such a piezoelectric layer is kept in the humid air, as exemplified in the relationship of current density-voltage of the thin film 2 in FIG. 12A and FIG. 12B, it was found that the decrease of the insulating breakdown voltage compared with the condition under the dry air is suppressed. It is thought that the effect of crack suppression and improvement of humidity resistance is based on the change of the alignment of the perovskite oxide including at least Bi, Ba, Fe, and Ti from the (110) face of natural alignment to the (100) face.

From the above description, to suppress the occurrence of cracks in the piezoelectric layer and to improve the humidity resistance, it is preferable to crystallize the precursor solution including at least Bi, Ba, Fe, and Ti to form the piezoelectric layer including the perovskite oxide preferentially aligned in (100) plane.

Before crystallization of the precursor solution 31, a first heating process of heating the application film 31 on the surface of the electrode 20 lower than a crystallization temperature of the perovskite oxide may be performed. The application film 31 is dry before the crystallization, and the application film 31 is degreased at a temperature equal to or higher than a degreasing temperature, and thus it is possible to satisfactorily form the piezoelectric layer 30. In addition, after the first heating process, a second heating process of heating the application film 31 on the surface of the electrode 20 equal to or higher than the crystallization temperature may be performed. By this burning, it is possible to satisfactorily form the piezoelectric layer 30. Various devices may be used in the heating. However, when an infrared lamp annealing device capable of using an RTA (Rapid Thermal Annealing) method is used in the heating equal to or higher than the crystallization temperature, it is possible to satisfactorily form the piezoelectric layer 30.

In the first heating process, it is drying temperature<degreasing temperature<crystallization temperature. Accordingly, after the application film 31 on the surface of the electrode 20 is heated at the drying temperature, and the application film 31 on the surface of the electrode 20 may be heated at the degreasing temperature after the drying process.

An alignment property of crystals may be analyzed as an X-ray diffraction chart by an X-ray diffraction wide angle method (XRD). As exemplified in the X-ray diffraction chart of the thin films 1 to 3 in FIG. 7A, it is difficult to see another aspect. In addition, the crystal structure of the piezoelectric layer 30 is estimated by pseudo cubic crystal in resolution of the X-ray diffraction device. The pseudo cubic crystal described herein means that a diffraction peak is not separated as much as considered as a≠c, does not mean that a=b=c is necessarily satisfied. However, there is no problem in analysis as cubic crystal in an alignment degree to be described hereinafter.

In the alignment property of the cubic crystal structure, generally, a Lotgering factor F acquired from the following formulas is used.

P₍₁₀₀₎=A₍₁₀₀₎/(A₍₁₀₀₎+A₍₁₁₀₎+A₍₁₁₁₎) (5)

F₍₁₀₀₎=(P₍₁₀₀₎−P₀₍₁₀₀₎))/(1−P₀₍₁₀₀₎) (6)

P₍₁₁₀₎=A₍₁₁₀₎/(A₍₁₀₀₎+A₍₁₁₀₎+A₍₁₁₁₎) (7)

F₍₁₁₀₎=(P₍₁₁₀₎−P₀₍₁₁₀₎)/(1−P₀₍₁₁₀₎) (8)

Herein, A₍₁₀₀₎ is a reflection intensity from the (100) alignment plane, A₍₁₁₀₎ is a reflection intensity from the (110) alignment plane, and A₍₁₁₁₎ is a reflection intensity from the (111) alignment plane. Accordingly, P₍₁₀₀₎ is a ratio of the reflection intensity from the (100) alignment plane with respect to a total reflection intensity, P₍₁₁₀₎ is a ratio of the reflection intensity from the (110) alignment plane with respect to a total reflection intensity. In addition, P₀₍₁₀₀₎ is a ratio of A₍₁₀₀₎ with respect to the total reflection intensity when crystals are not aligned, and P₀₍₁₁₀₎ is a ratio of A₍₁₁₀₎ with respect to the total reflection intensity when crystals are not aligned.

When platinum is used in the conductive film 21, a (111) peak of crystals is close to a peak of platinum, and thus the (111) peak is not separated with sufficient precision. For this reason, instead thereof, the alignment degree is calculated in the following calculation formulas.

P*₍₁₀₀₎=A₍₁₀₀₎/(A₍₁₀₀₎+A₍₁₁₀₎) (9)

F*₍₁₀₀₎=(P*₍₁₀₀₎−P*₀₍₁₀₀₎))/(1−P*₀₍₁₀₀₎) (10)

P*₍₁₁₀₎=A₍₁₁₀₎/(A₍₁₀₀₎+A₍₁₁₀₎) (11)

F*₍₁₁₀₎=(P*₍₁₁₀₎−P*₀₍₁₁₀₎)/(1−P*₀₍₁₁₀₎) (12)

Herein, P*₀₍₁₀₀₎ is a ratio of A₍₁₀₀₎ with respect to (A₍₁₀₀₎+A₍₁₁₀₎) when crystals are not aligned, and P*₀₍₁₁₀₎ is a ratio of A₍₁₁₀₎ with respect to (A₍₁₀₀₎+A₍₁₁₀₎) when crystals are not aligned. When the reflection intensity from the (100) alignment plane when crystals are not aligned is A₀₍₁₀₀₎, and the reflection intensity from the (110) alignment plane when crystals are not aligned is A₀₍₁₀₀₎, the following formulas are satisfied.

P*₀₍₁₀₀₎=A₀₍₁₀₀₎/(A₀₍₁₀₀₎+A₀₍₁₁₀₎) (13)

P*₀₍₁₁₀₎=A₀₍₁₀₀₎/(A₀₍₁₀₀₎+A₀₍₁₁₀₎) (14)

As exemplified in the alignment degree F*₍₁₀₀₎ of the thin films 1 to 3 in FIG. 7B, the piezoelectric layer formed on the electrode having LNO at least on the surface by the liquid phase method is preferentially aligned on the pseudo cubic crystal (100) face.

### 2. EXAMPLE OF METHOD OF MANUFACTURING PIEZOELECTRIC ELEMENT AND LIQUID EJECTION HEAD

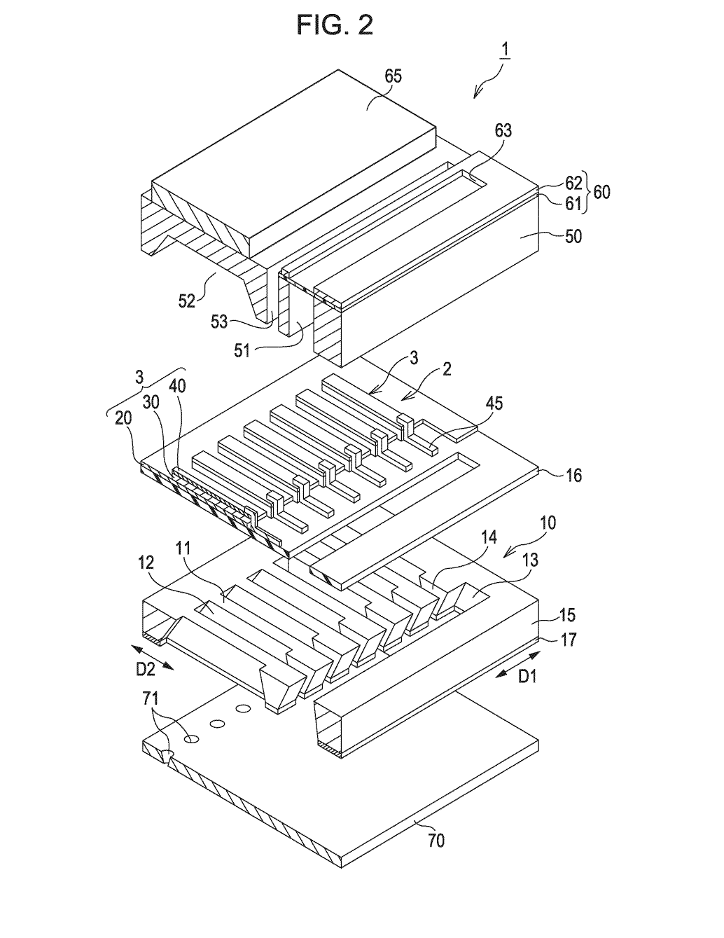

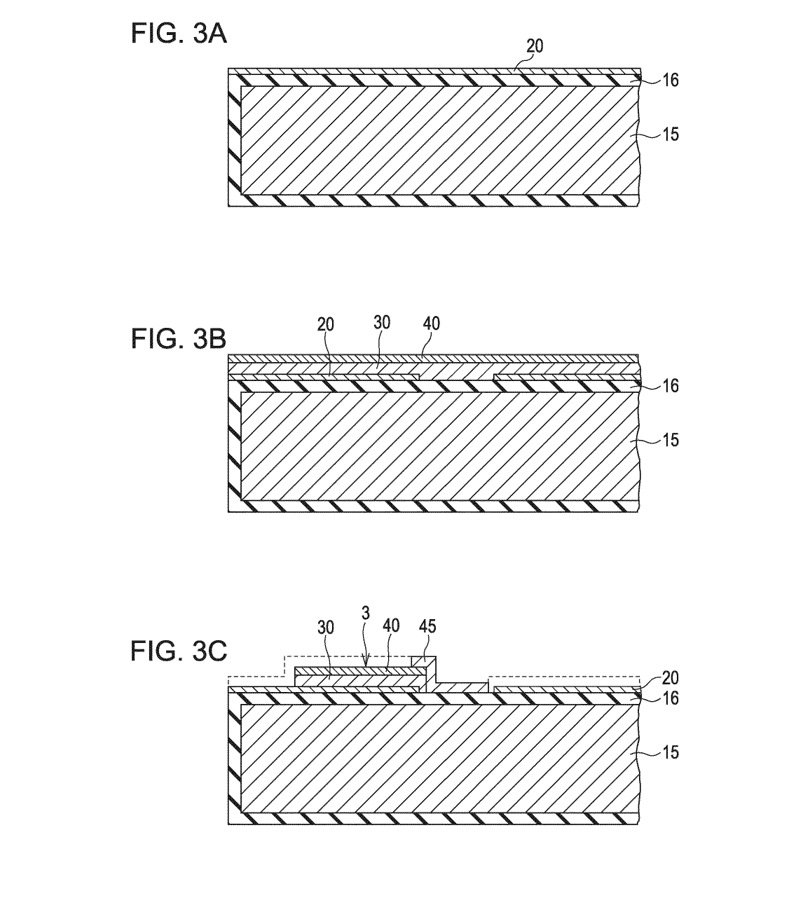

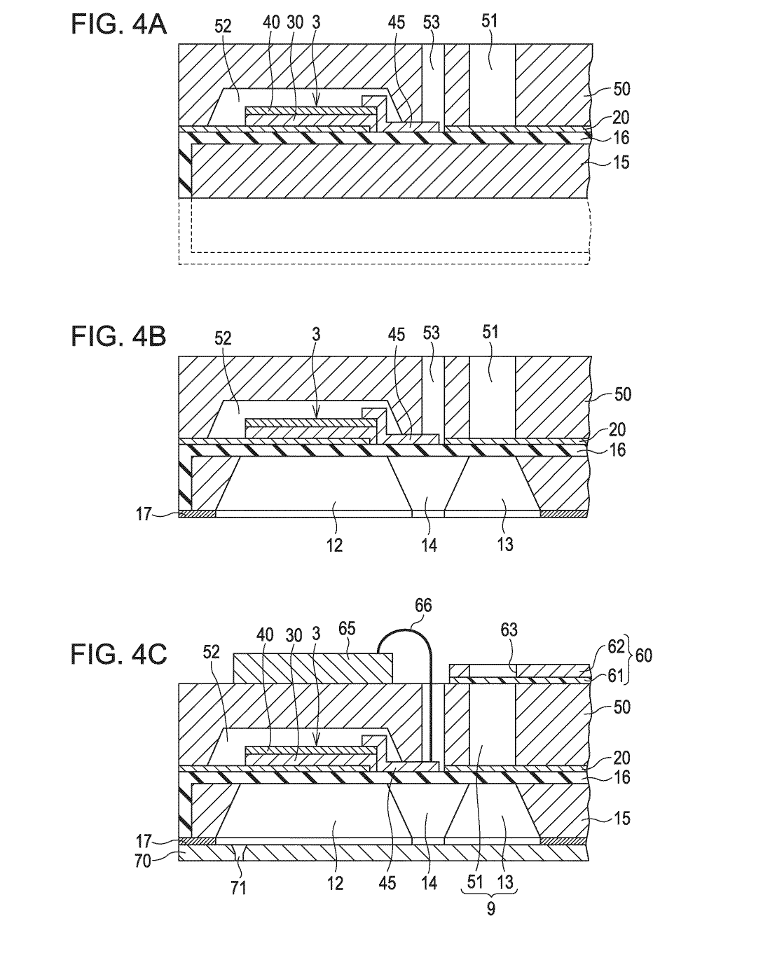

FIG. 2 is an exploded perspective view for convenience illustrating an ink jet recording head 1 that is an example of a liquid ejecting head. FIG. 3A to FIG. 4C are cross-sectional views illustrating an example of a method of manufacturing a recording head, and are vertical cross-sectional views taken along a longitudinal direction D2 of the pressure generation chamber 12. Layers constituting the recording head 1 may be adhered and laminated, and may be integrally formed, for example, by denaturalizing a surface of a non-separated material.

The flow path formation substrate 10 may be formed from a silicon single crystalline substrate or the like. The elastic film 16 may be integrally formed with the silicon substrate 15 by thermally oxidizing one face of the silicon substrate 15, in which a film thickness is relatively high, for example, about 500 to 800 μm, with high rigidity, in a diffusion furnace of about 1100° C., and may be formed of silicon dioxide (SiO₂) or the like. The thickness of the elastic film 16 is not particularly limited as long as it represents elasticity, but may be, for example, 0.5 to 2 μm.

Then, as shown in FIG. 3A, the lower electrode 20 is formed on the elastic film 16 by the sputtering method or the like. The lower electrode 20 is considered, for example, as shown in FIG. 1A, as a structure having the LNO film 22 preferentially aligned in (100) plane, on the conductive film 21.

One or more kinds of metals such as Pt, Au, Ir, and Ti may be used as the constituent metals of the conductive film 21. The thickness of the conductive film 21 is not particularly limited, but may be for example, about 50 to 500 nm. As an adhesive layer or a diffusion prevention layer, layers such as a TiAlN (titanium aluminum nitride) film, an Ir film, an IrO (iridium oxide) film, a zrO₂ (zirconium oxide) film may be formed on the elastic layer 16, and the conductive film 21 may be formed on the layers.

The LNO film 22 may be formed by applying the precursor solution on the surface of the conductive film 21, the elastic film 16, or the like by the liquid phase method such as the spin coating method (the application process 1) and crystallizing the application film. The precursor solution of the LNO film includes a solution in which at least lanthanum salt and nickel salt are dispersed in a solvent, a sol in which at least lanthanum salt and nickel salt are dispersed in a dispersion medium, and the like. The solvent or the dispersion medium may be a material including an organic solvent, for example, acetic anhydride. The lanthanum salt and the nickel salt may be an organic metal compound such as an organic acid salt, for example, acetate salt. It is standard that a molar concentration ratio of La (lanthanum) and Ni (nickel) in the precursor solution is 1:1, but may be deviated from 1:1. The precursor solution may include La and Ni as main components, and the other metal with a low molar ratio. When the LNO film 22 is heated equal to or higher than the crystallization temperature, the lower electrode 20 having LNO in a thin film state preferentially aligned in (100) plane at least on the surface thereof is formed. Preferably, it is heated and dried, for example, at about 140 to 190° C. (the drying process 1), then is heated and degreased, for example, at about 300 to 400° C. (the degreasing process 1), and then is heated and crystallized, for example, at about 550 to 850° C. (the burning process 1). The degreasing is to separate an organic component included in the application film, for example, as NO₂, CO₂, H₂O, or the like. The thickness of the LNO film 22 is not particularly limited, but may be, for example, 10 to 140 nm. In addition, in the example shown in FIG. 3B, the lower electrode 20 is formed, and then patterning is performed.

Then, as shown in FIG. 1, the precursor solution 31 including at least Bi, Ba, Fe, and Ti is applied onto the surface of the lower electrode 20 (the application process 2). Metal salt of at least Bi, Ba, Fe, and Ti included in the precursor solution may be organic salt such as 2-ethylhexanoic acid salt and acetate salt. The precursor solution includes a solution in which the metal salt is dissolved in a solvent, a collide solution in which the metal salt is dispersed in a dispersion medium, and the like. The solvent or the dispersion medium may be a material including an organic solvent such as octane, xylene, and combination thereof. A molar concentration ratio of metal in the precursor solution may be determined according to the composition of the formed perovskite oxide. It is standard that a molar concentration ratio of the A site constituent metal and the B site constituent metal in the formulas (1) to (4) described above is 1:1, but may deviate from 1:1 within a range where the perovskite oxide is formed. The thickness of the application film is not particularly limited, but may be, for example, 0.1 μm.

Then, the applied precursor solution 31 is crystallized to form the piezoelectric layer 30 including the perovskite oxide preferentially aligned in (100) plane. When the film of the precursor solution 31 is heated equal to or higher than the crystallization temperature of the perovskite oxide, the piezoelectric layer 30 in the thin film state including the perovskite oxide preferentially aligned in (100) plane is formed. Preferably, it is heated and dried, for example, at about 140 to 190° C. (the drying process 2), then is heated and degreased, for example, at about 300 to 400° C. (the degreasing process 2), and then is heated and crystallized equal to or higher than 450° C., for example, at about 550 to 850° C. (the burning process 2). To make the piezoelectric layer 30 thick, the combination of the application process 2, the drying process 2, the degreasing process 2, and the burning process 2 may be performed many times. To reduce the burning process 2, the burning process 2 may be performed after the combination of the application process 2, the drying process 2, and the degreasing process 2 are performed many times. In addition, the combination of such processes may be performed many times.

The thickness of the formed piezoelectric layer 30 is not particularly limited in a range representing an electromechanical transduction operation, but may be, for example, about 0.2 to 5 μm. Preferably, the thickness of the piezoelectric layer 30 is suppressed as much as cracks do not occur in the manufacturing process, and the piezoelectric layer 30 may be made thick to the extent of representing sufficient displacement characteristics.

The heating device for performing the drying processes 1 and 2 and the degreasing processes 1 and 2 described above may be a hot plate, an infrared lamp annealing device which performs heating by irradiation of an infrared lamp, and the like. The heating device for performing the burning processes 1 and 2 may be an infrared lamp annealing device, or the like. Preferably, it is preferable that a temperature increase rate be relatively high using the RTA (Rapid Thermal Annealing) method or the like.

After forming the piezoelectric layer 30, as shown in FIG. 3B, the upper electrode 40 is formed on the piezoelectric layer 30 by the sputtering method or the like. The constituent metal of the upper electrode 40 may be one or more kinds of metals such as Ir, Au, and Pt. The thickness of the upper electrode 40 is not particularly limited, but may be, for example, about 20 to 200 nm. In addition, in the example shown in FIG. 3C, after forming the upper electrode 40, the piezoelectric layer 30 and the upper electrode 40 are patterned in an area corresponding to each pressure generation chamber 12 to form the piezoelectric element 3.

Generally, any one electrode of the piezoelectric element 3 is a common electrode, and the other electrode and the piezoelectric layer 30 are patterned for each pressure generation chamber 12, thereby configuring the piezoelectric element 3. In the piezoelectric element 3 shown in FIG. 2 and FIG. 4A to 4C, the lower electrode 20 is a common electrode, and the upper electrode 40 is an individual electrode.

As described above, the piezoelectric element 3 having the piezoelectric layer 30 and the electrodes 20 and 40 is formed, and a piezoelectric actuator 2 provided with the piezoelectric element 3 and the elastic film 16 is formed.

Then, as shown in FIG. 3C, a lead electrode 45 is formed. For example, after a gold layer is formed over the whole face of the flow path formation substrate 10, and then is patterned for each piezoelectric element 3 through a mask pattern formed of resist or the like, thereby providing the lead electrode 45. Each upper electrode 40 shown in FIG. 2 is connected to a lead electrode 45 extending from an end portion vicinity on an ink supply path 14 side onto the elastic film 16.

The conductive film 21, the upper electrode 40, and the lead electrode 45 may be formed by a sputtering method such as a DC (direct current) magnetron sputtering method. A thickness of each layer may be adjusted by changing application voltage of a sputtering device or a sputtering process time.

Then, as shown in FIG. 4A, a protective substrate 50 in which a piezoelectric element storage unit 52 or the like is formed in advance is adhered onto the flow path formation substrate 10, for example, by an adhesive. The protective substrate 50 may be, for example, a silicon single crystal substrate, glass, a ceramic material, and the like. A thickness of the protective substrate 50 is not particularly limited, but may be, for example, about 300 to 500 μm. A reservoir unit 51 pierced in the thickness direction of the protective substrate 50 constitutes a reservoir 9 that is a common ink chamber (a liquid chamber), with a communication unit 13. The piezoelectric element storage unit 52 provided in the area corresponding to the piezoelectric element 3 has a space to the extent that movement of the piezoelectric element 3 is not disturbed. In a through-hole 53 of the protective substrate 50, the end portion vicinity of the lead electrode 45 drawn from each piezoelectric element 3 is exposed.

Then, the silicon substrate 15 is polished until it is some extent thickness, and then is further subjected to wet etching by fluoride nitric acid, such that the silicon substrate 15 is a predetermined thickness (for example, 60 to 80 μm). Then, as shown in FIG. 4B, a mask film 17 is newly formed on the silicon substrate 15, and is patterned in a predetermined shape. The mask film 17 may be formed of silicon nitride (SiN) or the like. Then, the silicon substrate 15 is subjected to anisotropy etching (wet etching) using an alkali solution such as KOH. Accordingly, a plurality of liquid flow paths provided with the pressure generation chambers 12 partitioned by a plurality of partition walls 11 and the ink supply paths 14 with a thin width, and the communication unit 13 that is the common liquid flow path connected to each ink supply path 14 are formed. The liquid flow paths 12 and 14 may be arranged in the width direction D1 that is a transverse direction of the pressure generation chamber 12.

In addition, the pressure generation chamber 12 may be formed before forming the piezoelectric element 3.

Then, unnecessary parts of the edge portions of the flow path formation substrate 10 and the protective substrate 50 are cut and removed by, for example, a dicing. Then, as shown in FIG. 4C, the nozzle plate 70 is adhered to the opposite face to the protective substrate 50 of the silicon substrate 15. The nozzle plate 70 may be glass ceramic, a silicon single crystal substrate, stainless steel, or the like, and is fixed to the passage face side of the flow path formation substrate 10. An adhesive, a thermal melting film, or the like may be used in the fixation. The nozzle plate 70 is provided with a nozzle passage 71 communicating with an end portion vicinity opposite to the ink supply path 14 of each pressure generation chamber 12. Accordingly, the pressure generation chamber 12 communicates with the nozzle passage 71 for ejecting the liquid.

Then, a compliance substrate 60 having a sealing film 61 and a fixing plate 62 is adhered onto the protective substrate 50, and is divided by a predetermined chip size. The sealing film 61 may be formed of, for example, a material having rigidity and low flexibility such as a polyphenylene sulfide (PPS) film with a thickness of about 4 to 8 μm, and seals one face of the reservoir unit 51. The fixing plate 62 may be formed of, for example, a hard material such as metal such as stainless steel (SUS) with a thickness of about 20 to 40 μm, and an area opposed to the reservoir 9 is an opening portion 63.

In addition, a driving circuit 65 for driving the piezoelectric element 3 provided in parallel is fixed onto the protective substrate 50. The driving circuit 65 may be formed of a circuit substrate, a semiconductor integrated circuit (IC), and the like. The driving circuit 65 and the lead electrode 45 are electrically connected through a connection line 66. The connection line 66 may be a conductive wire such as a bonding wire.

As described above, the recording head 1 is manufactured.

The recording head 1 takes ink from an ink inlet connected to an external ink supply unit (not shown), and the inside thereof is filled with the ink from the reservoir 9 to the nozzle passage 71. When voltage is applied between the lower electrode 20 and the upper electrode 40 for each pressure generation chamber 12 according to a recording signal from the driving circuit 65, ink droplets are ejected from the nozzle passage 71 by deformation of the piezoelectric layer 30, the lower electrode 20, and the elastic film 16.

In addition, the recording head may be considered as a common lower electrode structure in which the lower electrode is a common electrode and the upper electrode is an individual electrode, may be considered as a common upper electrode structure in which the upper electrode is a common electrode and the lower electrode is an individual electrode, and may be a structure in which the lower electrode and the upper electrode are common electrodes and an individual electrode is provided between both electrodes.

### 3. LIQUID EJECTING APPARATUS

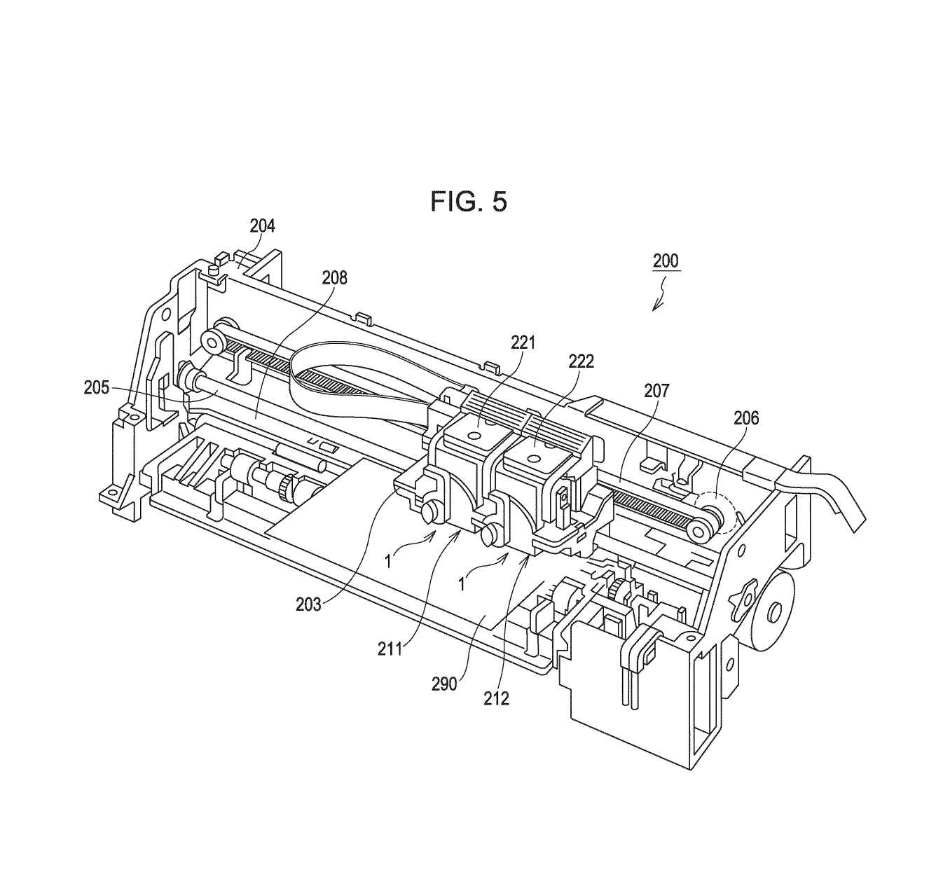

FIG. 5 shows an external appearance of a recording apparatus (a liquid ejecting apparatus) 200 having the recording head 1 described above. When the recording head 1 is provided in recording head units 211 and 212, it is possible to manufacture the recording device 200. The recording device 200 shown in FIG. 5 is provided with the recording head 1 for each of the recording head units 211 and 212, and ink cartridges 221 and 222 that are external ink supply units are detachably provided. The carriage 203 provided with the recording head units 211 and 212 is provided reciprocally along a carriage shaft 205 mounted on a device body 204. When the driving force of the driving motor 206 is transferred to the carriage 203 through a plurality of saw-toothed wheels (not shown) and a timing belt 207, the carriage 203 is moved along the carriage shaft 205. A recording sheet 290 fed by a sheet feeding roller (not shown) or the like is transported onto a platen 208, and printing is performed by ink supplied from the ink cartridges 221 and 222 and ejected from the recording head 1.

### 4. EXAMPLES

Hereinafter, examples will be described, but the invention is not limited to the following examples. Manufacturing LNO Precursor Solution for Thin Films 1 to 3

5 mmol of lanthanum acetate, 5 mmol of nickel acetate, 25 mL of acetic anhydride, and 5 mL water were mixed, and were heated to reflux at 60° C. for 1 hour, to manufacture the LNO precursor solution. Manufacturing BFM-BT Precursor Solution

All liquid materials of bismuth, iron, manganese, barium, and titanium having 2-ethylhexanoic acid with a ligand were mixed to be Bi:Fe:Mn=100:95:5, Ba:Ti=100:100, and BFM:BT=95:5 in a molar ratio of melted metal, to manufacture a BFM-BT precursor solution (a solution 1). Herein, BFM-BT is represented by a general formula (Bi, Ba)(Fe, Ti, Mn)O_{z}, the ratio of Bi:Fe:Mn:Ba:Ti=95:90.25:4.75:5:5. The BFM represents a molar number of Bi, that is, the sum of the molar numbers of Fe and Mn, and BT represents a molar number of Ba, that is, a molar number of Ti.

Similarly, a solution 2 of Bi:Fe:Mn=100:95:5, Ba:Ti=100:100, and BFM:BT=75:25, and a solution 3 of Bi:Fe:Mn=100:95:5, Ba:Ti=100:100, and BFM:BT=60:40 were manufactured. The BFM-BT of the solution 2 is Bi:Fe:Mn:Ba:Ti=75:71.25:3.75:25:25, and the BFM-BT of the solution 3 was Bi:Fe:Mn:Ba:Ti=60:57:3:40:40.

### Manufacturing of Thin Films 1 to 3

The substrate was a platinum-coated silicon substrate with one side size of 2.5 cm, specifically, a substrate having layers of Pt/TiOₓ/SiOₓ/Si. The LNO film and the BFM-BT film were formed on the substrate by the spin coating method.

First, the LNO precursor solution was dripped onto the substrate, and the substrate was rotated at 2200 rpm, to form the LNO precursor film (the application process 1). Then, it was heated on the hot plate of 180° C. for 5 minutes, and then was heated at 400° C. for 5 minutes (the drying and degreasing process 1). Then, it was burnt at 750° C. for 5 minutes at a high temperature by the RTA method using the infrared lamp annealing device (the burning process 1). By the processes described above, the LNO film preferentially aligned in (100) plane with a thickness of 40 nm was manufactured.

Then, the solution 2 was dripped onto the LNO film, and the substrate was rotated at 3000 rpm, to form the BFM-BT precursor film (the application process 2). Then, it was heated on the hot plate of 150° C. for 2 minutes, and then was heated at 350° C. for 5 minutes (the drying and degreasing process 2). Combination of the application process 2 and the drying and degreasing process 2 was repeated three times, and then it was burnt at 650° C. for 3 minutes by the RTA method using the infrared lamp annealing device (the burning process 2). Combination of “the combination of the application process 2 and the drying and degreasing process 2 three times” and “the burning process 2” was repeated twice, to form the LNO film and the BFM-BT film on the substrate. The formed LNO film and BFM-BT film were the thin film 1. A thickness of the thin film 1 was 468 nm.

Similarly, combination of “the combination of the application process 2 and the drying and degreasing process 2 three times” and “the burning process 2” was repeated four times, to manufacture the thin film 2 in which a thickness of combination of the LNO film and the BFM-BT film was 932 nm. In addition, combination of “the combination of the application process 2 and the drying and degreasing process 2 three times” and “the burning process 2” was repeated five times, to manufacture the thin film 3 in which a thickness of combination of the LNO film and the BFM-BT film was 1270 nm.

### Manufacturing of Upper Electrode

A platinum pattern with a thickness of about 100 nm was manufactured on the thin film 1 using a metal mask by DC sputtering. Then, printing was performed on the thin film at 650° C. for 5 minutes using the infrared lamp annealing device by the RTA method to manufacture the piezoelectric element (the element 1) having layers of Pt/BFM-BT/LNO (the upper electrode formation process 1).

Similarly, the elements 2 and 3 were manufactured using the thin films 2 and 3.

### Comparative Example 1

A comparative thin film 1 was manufactured in the same process as that of the thin film 1, except that the heating process of 350° C. performed in the degreasing process 2 of the thin film 1 was changed to 450° C. A thickness of combination of the LNO film and the BFM-BT film was 472 nm.

Then, a comparative element 1 was manufactured in the same process as that of the upper electrode formation process 1.

### Comparative Example 2

A comparative thin film 2 of total 12 layers was manufactured using the solution 2 without forming the LNO film on the platinum-coated silicon substrate, in the same process as the application process 2, the drying and degreasing process 2, and the burning process 2. A thickness of the BFM-BT film formed on the substrate was 924 nm.

Then, a comparative element 2 was manufactured in the same process as the upper electrode formation process 1.

### Test Example 1

Measurement of thermo gravimetric scanning piping hot weight simultaneous differential thermal analysis (measurement of TG-DTA) was performed on the solutions 1, 2, and 3. The measurement of TG-DTA was performed using a “TG-DTA2000SA” manufactured by Bruker in a temperature range of a room temperature to 525° C. at an elevating temperature rate of 5° C./min under the air atmosphere.

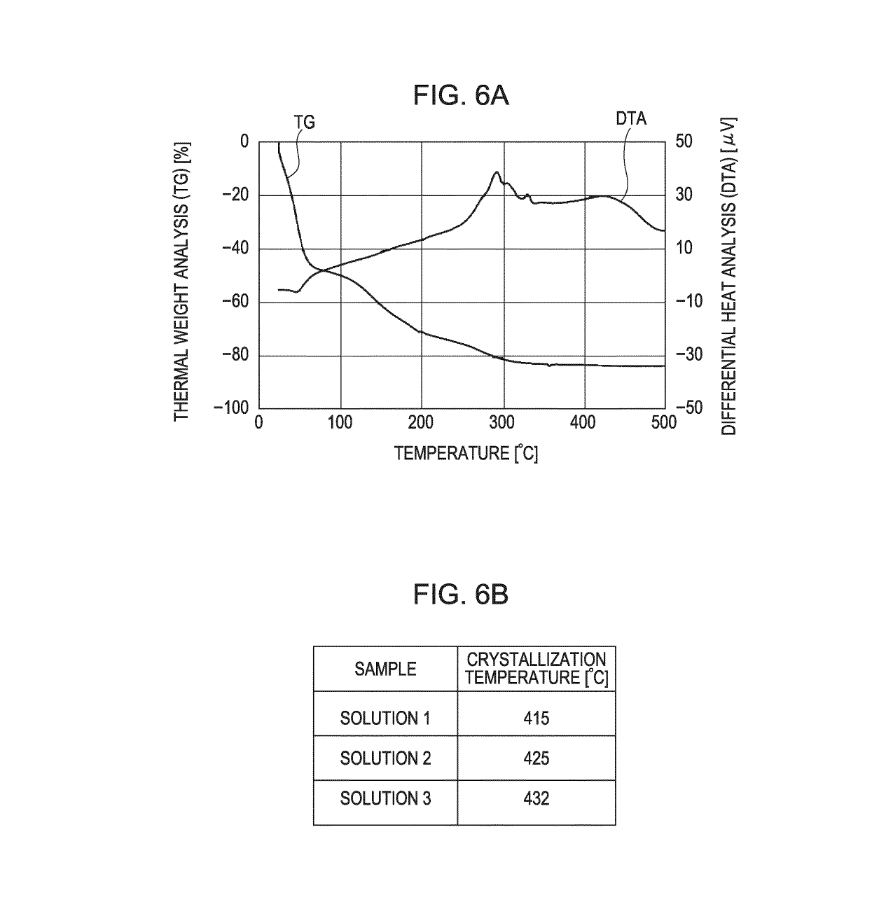

In FIG. 6A, as an example of the result, the TG-DTA measurement result of the solution 2 is shown. As shown in FIG. 6A, at the room temperature to 230° C., weight decrease of TG and an endothermic peak of DTA were observed, and thus it can be known that volatilization of a solvent mainly occurs. At 230 to 340° C., a weight decrease of TG and an exothermic peak of DTA were observed, and thus it can be known that dissolution of a complex and volatilization and dissolution of a ligand occur. At 410 to 500° C., there is no change in TG, only change of specific heat of DTA was observed, and thus it can be known that crystallization is being performed.

In FIG. 6B, the crystallization temperature of the perovskite oxide investigated from the TG-DTA measurement result is shown. The crystallization temperature described herein was a point of starting occurrence of the change of specific heat of DTA. As shown in FIG. 6B, the crystallization temperature based on the precursor solution including at least Bi, Ba, Fe, and Ti falls within 400 to 450° C.

### Test Example 2

With respect to the thin films, 1, 2, and 3, and the comparative thin films 1 and 2, an X-ray diffraction chart was acquired using “D8 Discover” manufactured by Bruker by the X-ray diffraction wide angle method (XRD) using CuKα as an X-ray source.

The result is shown in FIG. 7A. As shown in FIG. 7A, in all of the thin films 1 to 3 and the comparative examples 1 and 2, the BFM-BT with the perovskite structure was formed, and the other shape could not be seen. In addition, the crystallization structure of the thin films 1 to 3 is estimated by pseudo cubic crystal in resolution of the X-ray diffraction device. Accordingly, the alignment degree of crystals is analyzed as cubic crystal, and there is no problem. In the chart shown in FIG. 7A, the (111) peak of BFM-BT is close to a strong peak of platinum, and thus it is difficult to separate the (111) peak with sufficient precision. Therein, instead of the Lotgering factor F, the factors F*₍₁₀₀₎ and F*₍₁₁₀₎ were calculated by the formulas (9) to (12). P*₍₁₀₀₎ and P*₍₁₀₀₎ were P*₀₍₁₀₀₎=0.24 and P*₀₍₁₁₀₎=0.76 acquired using a bulk of BFM-BT.

In FIG. 7B, the calculation result of the factor F*₍₁₀₀₎ and F*₍₁₁₀₎ is shown. As shown in FIG. 7B, in the comparative thin film 2 in which BFM-BT is formed on the surface of the electrode without LNO, it can be known that it is preferentially aligned in (110) plane. In the comparative thin film 1 in which the heating process of the degreasing process 2 is performed at the crystallization temperature investigated in TG-DTA, it can be known that it is F*₍₁₀₀₎=0.04 and an alignment degree of the (100) face and an alignment degree of the (110) face that is a natural alignment plane are the same. Meanwhile, in the thin films 1 to 3 in which BFM-BT is formed on the surface of the electrode having LNO, it can be known that every F*₍₁₀₀₎ is equal to or more than 0.5 and it is preferentially aligned in (100) plane.

### Test Example 3

With respect to the thin films 1 to 3 and the comparative thin films 1 and 2, to investigate the fracture surface state, observation was performed by an SEM (a scanning electron microscope).

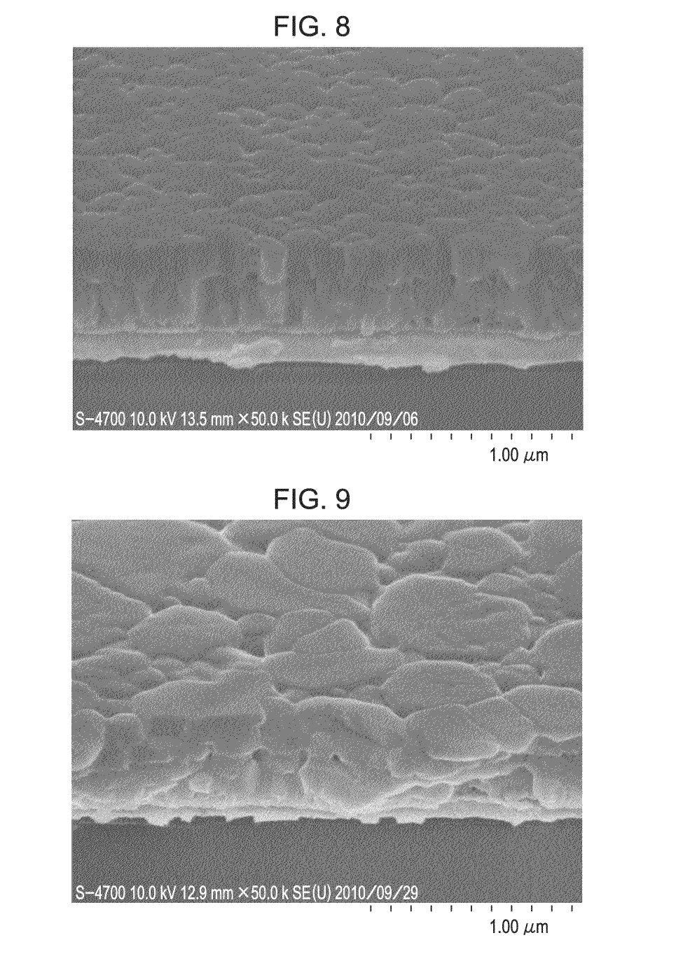

In FIG. 8, a photographic image of a fracture cross-section of the thin film 1 captured by an SEM is shown, and in FIG. 9, a photographic image of a fracture cross-section of the comparative thin film 1 captured by an SEM is shown. As shown in FIG. 8 and FIG. 9, it was found that the thin film 1 was pillar-shaped crystals in which crystal was connected in the thickness direction over an interface based on rapid heating of the RTA method, but in the comparative thin film 1, the amount of pillar-shaped crystals were small and particle-shaped crystals occupied most of parts. When the heating temperature of the drying and degreasing process 2 is lower than the crystallization temperature investigated in TG-DTA as the thin film 1, it is thought that it is because a probability of generation of crystal nucleus is low in the drying and degreasing process 2, and generation and growth of the crystal nucleus selectively proceeds on the lower interface at the time of rapid heating of the RTA method, and the pillar-shaped crystals are formed. Meanwhile, when the temperature of the drying and degreasing process 2 is substantially the same as the crystallization temperature investigated in TG-DTA as the comparative thin film 1, it is thought that it is because the crystal nucleus is generated in the film in the drying and degreasing process 2 by a random probability. This result coincides with the result in which F*₍₁₀₀₎ acquired from the X-ray diffraction chart based on XRD in the comparative thin film 1 is less than 0.5.

### Test Example 4

With respect to the thin film 2 and the comparative thin film 2, the dark-field image of the surface was taken using a metal microscope.

In FIG. 10, a dark-field image of the thin film 2 is shown, and in FIG. 11, a dark-field image of the comparative thin film 2 is shown. As shown in FIG. 11, when BFM-BT was formed on the surface of the electrode without LNO, it can be known that cracks occur in the piezoelectric layer. Meanwhile, as shown in FIG. 10, when the piezoelectric layer including Bi, Ba, Fe, and Ti preferentially aligned in (100) plane was formed on the surface of the electrode having LNO preferentially aligned in (100) plane on the surface, it is found that cracks do not occur in the piezoelectric layer.

### Test Example 5

With respect to the element 2 and the comparative element 2, a relationship (Log(J)−E Curve) between common logarithm Log(J) of current density J (A/cm²) and voltage E (V) was acquired by applying voltage of ±60 V under the dry air and humid air of 50%. The measurement under the dry air was performed while supplying the dry air into a box in which an element sample is put. The measurement under humid air was performed without putting the element sample into the box.

In FIG. 12A, a relationship of current density (logarithm)-voltage under the dry air is shown, and in FIG. 12B, a relationship of current density (logarithm)-voltage under humid air is shown. Herein, “the thin film 2” represents data obtained by applying voltage to the element 2, and “the comparative thin film 2” represents data obtained by applying voltage to the comparative element 2.

As shown in FIG. 12A, under the dry air, difference is not substantially shown in characteristics between a case of forming BFM-BT on the surface of the electrode without LNO as the comparative element 2, and a case of forming the piezoelectric layer including Bi, Ba, Fe, and Ti preferentially aligned in (100) plane on the surface of the electrode having LNO on the surface thereof as the element 2.

As shown in FIG. 12B, under humid air, when BFM-BT is formed on the surface of the electrode without LNO as the comparative element 2, it can be known that an insulating breakdown voltage is decreased. Meanwhile, when the piezoelectric layer including Bi, Ba, Fe, and Ti preferentially aligned in (100) plane is formed on the surface of the electrode having LNO on the surface thereof as the element 2, it can be known that the decrease of the leak level compared with the condition under the dry air is suppressed, and the decrease of the insulating property of the piezoelectric layer is suppressed.

### Test Example 6

With respect to the elements 1 to 3 and the comparative examples 1 and 2, a relationship (P−E curve) between a polarization amount P (μC/cm²) and electric field E (V) was acquired by applying a triangle wave of frequency of 1 kHz at the room temperature using an electrode pattern of Φ=500 μm using “FCE-1A” manufactured by Toyo Technica Co., Ltd.

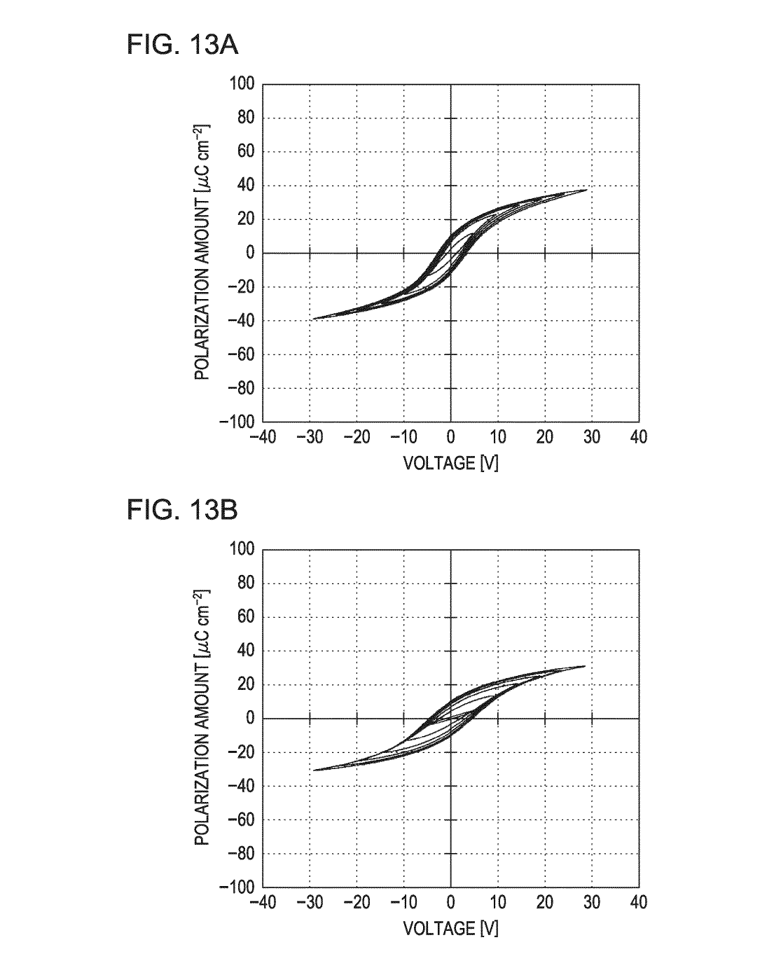

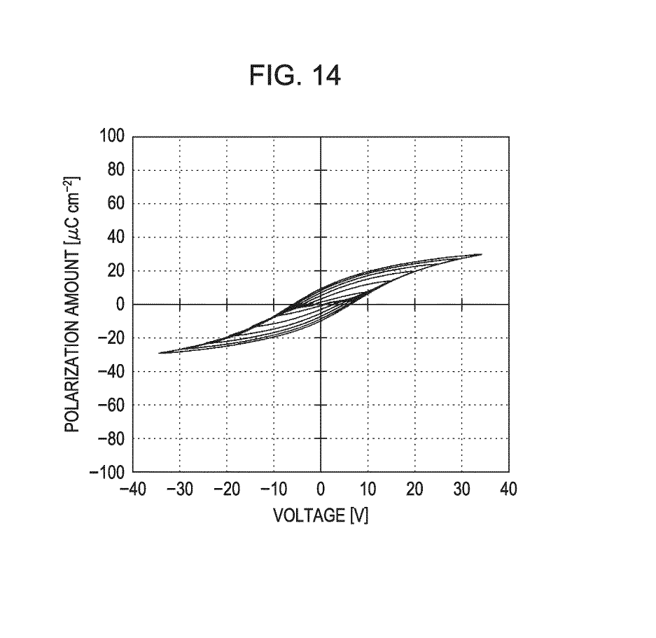

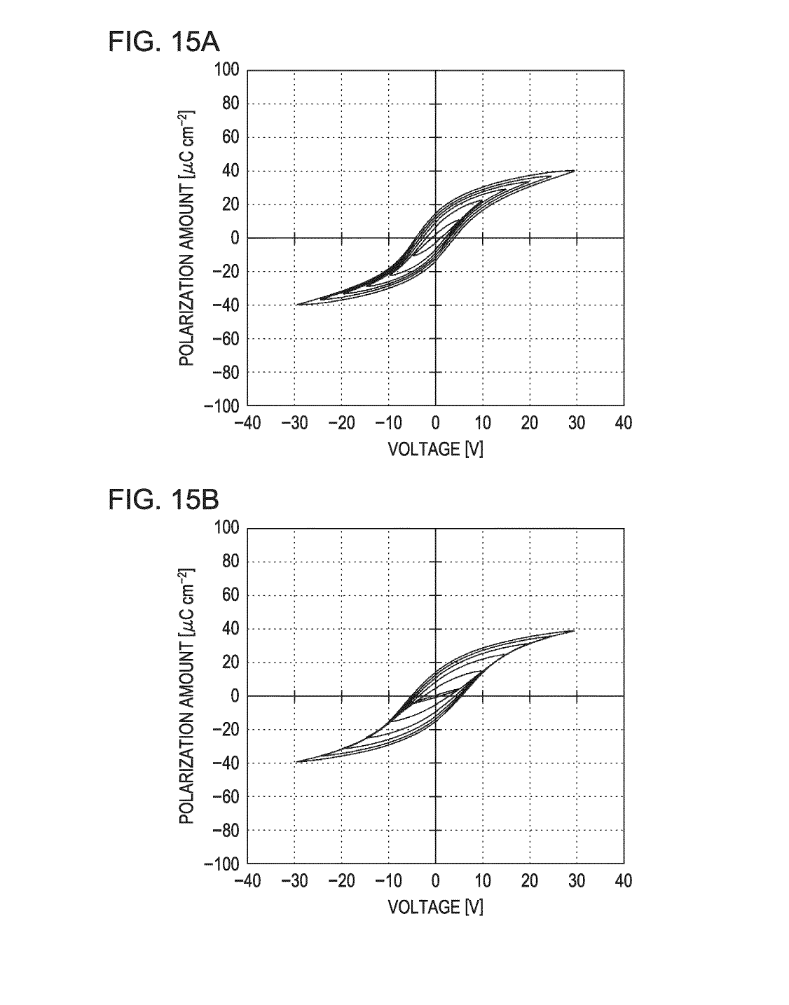

In FIG. 13A and FIG. 13B, P-E curves of the elements 1 and 2 are shown, in FIG. 14, a P-E curve of the element 3 is shown, and in FIG. 15A and FIG. 15B, P-E curves of the comparative elements 1 and 2 are shown. As shown in FIG. 13A to FIG. 15B, it was known that all of the elements 1 to 3 and the comparative elements 1 and 2 represent satisfactory P-E hysteresis, and represents satisfactory piezoelectric characteristics without depending on the alignment property or the like.

### Test Example 7

With respect to the elements 1 to 3 and the comparative elements 1 and 2, a relationship between electric-field-induced strain (nm) and voltage (V) was acquired by applying a triangle wave of frequency of 1 kHz at the room temperature using an electrode pattern of Φ=500 μm using a displacement measurement device (DBLI) manufactured by Aixacct Systems.

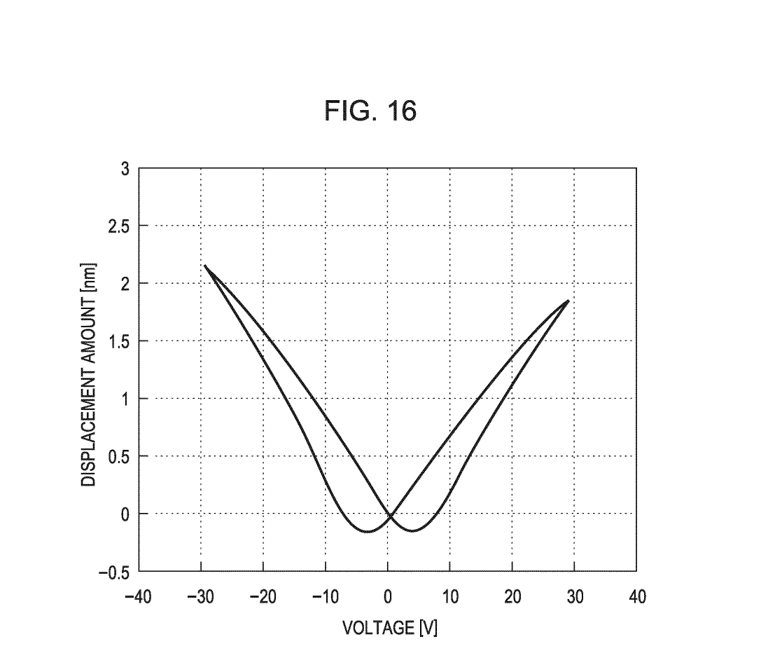

In FIG. 16, as an example of the result, a relationship between electric-field-induced strain and voltage of the element 2 is shown. As shown in FIG. 16, by applying alternating current frequency of 30 V, a butterfly curve of reached strain is 1.837 nm and a reverse reached strain is −0.164 nm is shown. From this, when a difference of the reverse reached strain on the minus side from the reached strain from the plus side is the maximum strain, the maximum strain is 2.037 nm. This is 0.22% in conversion of distortion. Accordingly, when the piezoelectric layer including Bi, Ba, Fe, and Ti preferentially aligned in (100) plane is formed on the surface of the electrode having LNO on the surface thereof as the element 2, it can be known that satisfactory electric field induced strain characteristics are represented.

From the above description, the electrode having LNO preferentially aligned in (100) plane at least on the surface thereof is formed, the precursor solution including at least Bi, Ba, Fe, and Ti is applied onto the surface of the electrode, and the applied precursor solution is crystallized to form the piezoelectric layer including the perovskite oxide preferentially aligned in (100) plane. Accordingly, it is possible to manufacture satisfactory (100) alignment ceramic, and it can be known that the piezoelectric element using the same represents satisfactory electric field induced strain characteristics. Accordingly, the manufacturing method can improve performance of the piezoelectric element having the piezoelectric layer including Bi, Ba, Fe, and Ti, the liquid ejecting head, and the liquid ejecting apparatus.

### Manufacturing of Thin Films 4 to 10

The LNO precursor solution was manufactured as follows.

First, in the air, lanthanum acetate 1.5 hydrate (La(CH₃COO)₃.1.5H₂O and nickel acetate tetrahydrate (Ni(CH₃COO)₂.4H₂O) were added to a beaker such that each of lanthanum and nickel was 5 mmol. Thereafter, 20 mL of propionic acid (concentration: 99.0 weight %) was added and mixed. Thereafter, heating was performed such that the temperature of the solution was about 140° C., and was stirred for about 1 hour while timely dripping propionate so as not to be bonfire, thereby manufacturing the LNO precursor solution.

The substrate was a platinum-coated silicon substrate with one side size of 6 inch, specifically, a substrate having layers of Pt/Zr/ZrOₓ/SiOₓ/Si was used. The substrate was manufactured as follows.

First, a silicon dioxide film was formed on a surface of a silicon substrate by thermal oxidization. Then, a zirconium film was manufactured on the silicon dioxide film by the sputtering method, and thermal oxidization was performed, thereby forming a zirconium oxide film. Then, a platinum film aligned in (111) was laminated on the zirconium oxide film by 50 nm.

The LNO film was manufactured as follows.

First, the LNO precursor solution was dripped onto the platinum film of the substrate, and the substrate was rotated at 2000 rpm, thereby forming the LNO precursor film (the application process 1). Thereafter, heating was performed at 330° C. for 5 minutes (the drying and degreasing process 1). Thereafter, it was burnt and crystallized at the oxygen atmosphere at 750° C. for 5 minutes by the RTA method using the infrared lamp annealing device (the burning process 1), thereby forming the LNO film preferentially aligned in (100) plane with a thickness of about 30 nm.

A substrate obtained by angularly cutting the LNO film-formed substrate by 2.5 cm was used in the manufacturing of the thin films 4 to 10. The BFM-BT precursor solution was the solution 2 (BFM:BT=75:25) described above. The thin films 4 to 10 were manufactured as follows.

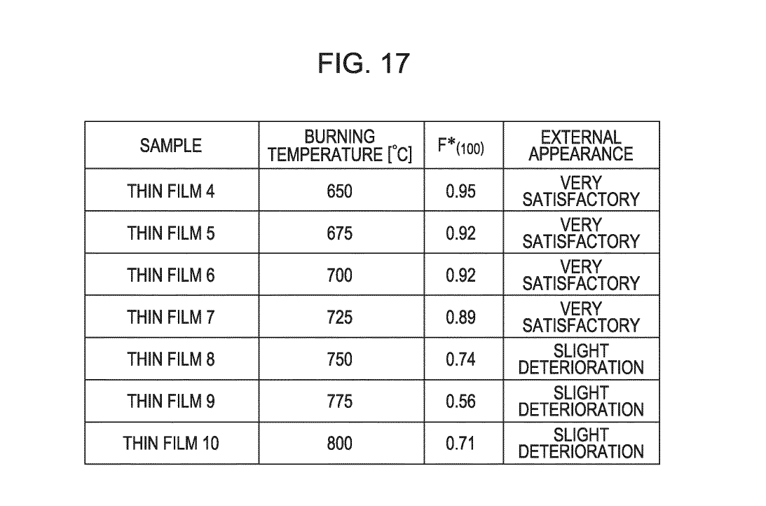

First, the BFM-BT precursor solution was dripped onto the LNO film of the substrate, and the substrate was rotated at 3000 rpm, to form the BFM-BT precursor film (the application process 2). Then, it was heated on the hot plate at 180° C. for 2 minutes, and then was heated at 350° C. for 3 minutes (the drying and degreasing process 2). The combination of the application process 2 and the drying and degreasing process 2 was repeated twice, and then it was burnt at a burning temperature shown in FIG. 17 for 5 minutes (the burning process 2). Combination of “the combination of the application process 2 and the drying and degreasing process 2 twice” and “the burning process 2” was repeated six times, to form the LNO film and the BFM-BT film on the substrate. The formed LNO film and BFM-BT film were the thin films 4 to 10. As an example of the thickness of the thin film, the thickness of the thin film 4 was 900 nm.

An iridium (Ir) pattern with a thickness of about 50 nm was manufactured on the thin films 4 to 10 using a metal mask by sputtering, thereby manufacturing the piezoelectric elements (the elements 4 to 10) having layers of Ir/BFM-BT/LNO.

### Manufacturing of Comparative Thin Films 4 to 10

The comparative thin films 4 to 10 and the comparative elements 4 to 10 were manufactured in the same process as the manufacturing process of the elements 4 to 10 except that the process of forming LNO is omitted. For convenience, in the specification, the “comparative thin film 3” and the “comparative element 3” are not described.

### Test Example 8

With respect to the thin films 4 to 10 and the comparative thin films 4 to 10, the X-ray diffraction chart was acquired in the same manner as Test Example 2. As a result, in all of the thin films 4 to 10 and the comparative thin films 4 to 10, the perovskite structure BFM-BT was formed, and it was difficult to see the other aspect. Even in Test Example 8, the (111) peak of BFM-BT is close to a strong peak of platinum, and thus it is difficult to separate the (111) peak with sufficient precision. Therein, the factors F*₍₁₀₀₎ and F*₍₁₀₀₎ were calculated using P*₀₍₁₀₀₎=0.24 and P*₀₍₁₁₀₎=0.76. As a result, it was known that all the comparative thin films 4 to 10 in which BFM-BT was formed on the surface of the electrode without LNO were preferentially aligned in (110) plane. Meanwhile, in all the thin films 4 to 10, as shown in FIG. 17, it can be known that F*₍₁₀₀₎ is equal to or more than 0.5 and is preferentially aligned in (100) plane.

As shown in FIG. 17, in the thin films 8 to 10 with a burning temperature of 750° C. or higher, the factor F*₍₁₀₀₎ was equal to or less than 0.74, but in the thin films 4 to 7 with a burning temperature of 725° C. or lower, the factor F*₍₁₀₀₎ was equal to or more than 0.89, that is, the alignment degree was increased.

### Test Example 9

In the thin films 4 to 10, a dark-field image on the surface was taken using a metal microscope. In FIG. 17, an external appearance of the thin film surface is shown. As shown in FIG. 17, the thin films 4 to 7 with the burning temperature of 725° C. or lower have a very satisfactory appearance without cracks. In the thin films 8 to 10 with the burning temperature of 750° C. or higher, slight crack occurrence could be seen although it is less than that of the comparative thin films in which BFM-BT is formed on the surface of the electrode without LNO. From this, when the piezoelectric layer including BFM-BT preferentially aligned in (100) plane is formed on the surface of the electrode having LNO, it is possible to obtain the effect of suppressing the crack occurrence of the piezoelectric layer. However, when the burning temperature is equal to or less than 725° C., it can be known that the crack occurrence of the piezoelectric layer is further suppressed.

### Test Example 10

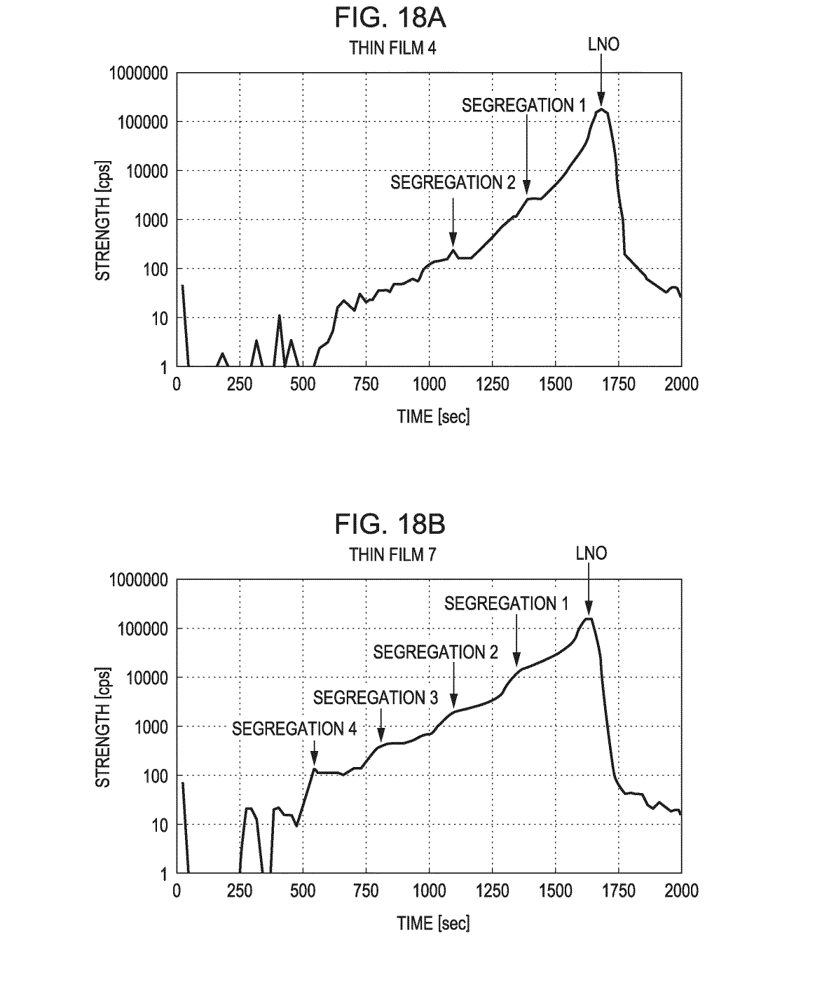

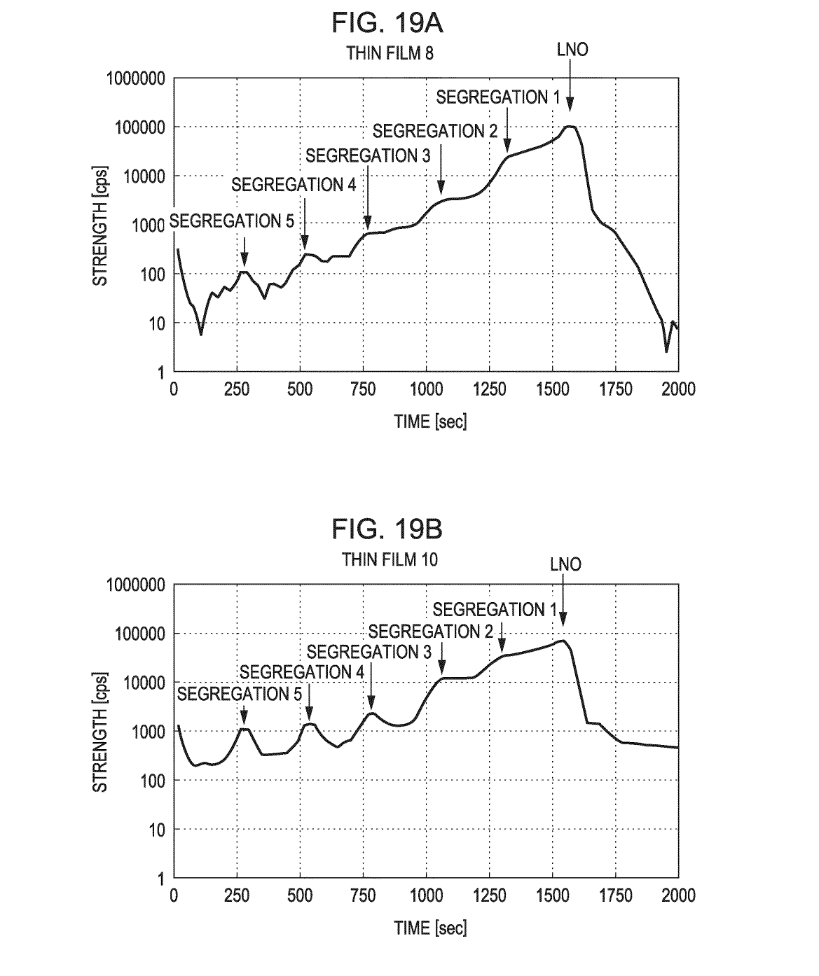

With respect to the thin films 4 to 10 and the comparative thin films 4, secondary ion mass analysis was performed in the thickness direction from the piezoelectric layer, and distribution of lanthanum (La) was investigated. As a secondary ion mass analysis device (SIMS), “ADEPT-1010” manufactured by Ulvac-Phi, Inc. was used. As an example of the result, an SIMS profile of lanthanum of the thin film 4 is shown in FIG. 18A, an SIMS profile of lanthanum of the thin film 7 is shown in FIG. 18B, an SIMS profile of lanthanum of the thin film 8 is shown in FIG. 19A, and an SIMS profile of lanthanum of the thin film 10 is shown in FIG. 19B. In the measurement, lanthanum is affected by disturbance elements in BFM-BT, and thus a background process was performed using the profile of the comparative thin film 4 which did not include lanthanum. In the drawings, the horizontal axis represents a measurement time (unit: second), the vertical axis represents common logarithm of intensity (unit: cps) of lanthanum, the left side represents the piezoelectric layer surface side, the right side represents the platinum-coated silicon substrate, and the “LNO” represents a position of the LNO film. Segregation estimated to occur on the interface of the burning performed six times at the time of forming the BFM-BT film is indicated by “Segregation 1”, “Segregation 2”, “Segregation 3”, “Segregation 4”, and “Segregation 5” in order. In addition, the surface performed when the burning process 2 is performed at the n-th time (n is an integer of 1 to 5) is called a burning interface n. Accordingly, the burning interface 5 is an interface on the surface side farthest from the LNO film except for the surface in the piezoelectric layer.

As shown in FIG. 18A, the piezoelectric layer of the thin film 4 with a burning temperature of 650° C. includes lanthanum considered to be diffused from the LNO film. In addition, the distribution of lanthanum is not uniform, and segregations (segregations 1 and 2) of lanthanum were observed in the burning interfaces 1 and 2. In the thin films 5 and 6, segregations (segregations 1 to 3) of lanthanum were observed in the burning interfaces 1 to 3. In the thin film 7 with a burning temperature of 725° C., as shown in FIG. 18B, segregations (segregations 1 to 4) of lanthanum were observed in the burning interfaces 1 to 4. In the thin film 8 with a burning temperature of 750° C., as shown in FIG. 19A, segregations (segregations 1 to 5) of lanthanum were observed in the burning interfaces 1 to 5. Even in the thin film 9, segregations (segregations 1 to 5) of lanthanum were observed in the burning interfaces 1 to 5. Even in the thin film 10 with a burning temperature of 800° C., as shown in FIG. 19B, segregations (segregations 1 to 5) of lanthanum were observed in the burning interfaces 1 to 5.

As described above, when the burning temperature is equal to or higher than 750° C., it is possible to see the segregation 5 of lanthanum in the burning interface 5 on the most surface side. In this case, it is F*₍₁₀₀₎≦0.74. Meanwhile, when the burning temperature is equal to or lower than 725° C., it is difficult to see the segregation 5 of lanthanum in the burning interface 5. In this case, it is F*₍₁₀₀₎≧0.89, and it is possible to obtain a preferable piezoelectric element in which crack occurrence of the piezoelectric layer is suppressed. It is thought that this is because of the following reason.

When the burning temperature is relatively high equal to or higher than 750° C., it is estimated that a ratio in which the crystals formed in the (n−1)-th burning process 2 are re-dissolved in the n-th burning process 2 is high, and thus a ratio in which La derived from the LNO film is diffused on the surface side of the piezoelectric layer is high. Accordingly, it is thought that it is possible to see the segregation 5 of La in the burning interface 5 on the most surface side. When the segregation of La occurs on a relatively large amount of burning interfaces 1 to 5, it is estimated that continuity of crystal growth is discontinuous in the relatively large amount of burning interfaces, the crystals grow without prolonging the alignment of crystals in the lower layer, and the alignment degree of (100) is decreased. From the observation result of the external appearance of the thin film surface, it is thought that, when the alignment degree of (100) is decreased, the effect of suppressing the crack occurrence of the piezoelectric layer is decreased.

Meanwhile, when the burning temperature is relative low equal to or lower than 725° C., it is estimated that a ratio in which the crystals formed in the (n−1)-th burning process 2 are re-dissolved in the n-th burning process 2 is low, and a ratio in which La derived from the LNO film is diffused on the surface side of the piezoelectric layer is low. Accordingly, it is thought that the segregation 5 of La does not occur in the burning interface 5 on the most surface side. When the amount of burning interface in which the segregation of La occurs is small, it is estimated that the continuity of the crystal growth is kept, the crystals are grown while prolonging the alignment of the crystals of the layer, and the alignment degree of (100) is increased. From the observation result of the external appearance of the thin film surface, when the alignment degree of (100) is increased, it is thought that the effect of suppressing the crack occurrence of the piezoelectric layer is increased.

### Test Example 11

With respect to the thin films 4 to 6, similarly to Test Example 5, a relationship (Log(J)−E Curve) between common logarithm Log(J) of current density J (A/cm²) and voltage E (V) was acquired under the dry air and humid air of 50%. As a result, even in any thin film, it was confirmed that the decrease of the leak level compared with the condition under the dry air is suppressed, and the decrease of the insulating property of the piezoelectric layer is suppressed.

From the above description, it was possible to obtain a new acknowledge that, when the factor F*₍₁₀₀₎ was 0.89 or more, a preferable piezoelectric element in which the crack occurrence of the piezoelectric layer was suppressed was obtained.

### 5. APPLICATION, OTHERS

The invention may be variously modified.

In the embodiment, the individual piezoelectric body is provided for each pressure generation chamber, but a common piezoelectric body may be provided for a plurality of pressure generation chambers and an individual electrode may be provided for each pressure generation chamber.

In the embodiment, a part of the reservoir is formed on the flow path formation substrate, but the reservoir may be formed in a member different from the flow path formation substrate.

In the embodiment, the upside of the piezoelectric element is covered with the piezoelectric element storage unit, but the upside of the piezoelectric element may be opened to the air.

In the embodiment, the pressure generation chamber is provided on the opposite side to the piezoelectric element, far away from the vibration plate, but the pressure generation chamber may be provided on the piezoelectric element side. For example, when a space surrounded between fixed plates and between piezoelectric elements is formed, the space may be the pressure chamber generation chamber.

The liquid ejected from the fluid ejecting head may be a material which can be ejected from the liquid ejecting head, and includes a fluid such as a solution in which a dye or the like is dissolved in a solvent, and a sol in which solid particles such as pigments or metal particles are dispersed in a dispersion medium. Such a fluid includes ink, liquid crystal, and the like. The liquid ejecting head also includes a head which ejects powder or gas. The liquid ejecting head may be mounted on a device of manufacturing a color filter such as a liquid crystal display, a device of manufacturing an electrode of an organic EL display or the like, a bio-chip manufacturing device, or the like, in addition to an image recording apparatus such as a printer.

Laminated ceramic manufactured by the manufacturing method described above may be very appropriately used to form a ferroelectric device, a pyroelectric device, a piezoelectric device, and a ferroelectric thin film of an optical filter. The ferroelectric device may be a ferroelectric memory (FeRAM), a ferroelectric transistor (FeFET), or the like, the pyroelectric device may be a temperature sensor, an infrared detector, a temperature-electric converter, or the like, the piezoelectric device may be a fluid ejection device, an ultrasonic motor, an acceleration sensor, a pressure-electric converter, or the like, and the optical filter may be a block filter of harmful light such as infrared light, an optical filter using a photonic crystal effect based on quantum dot formation, and an optical filter using optical interference of a thin film.

As described above, according to the invention, by various aspect, it is possible to provide a technique of improving performance of the piezoelectric element provided with the piezoelectric layer including at least Bi, Ba, Fe, and Ti by the liquid phase method, the liquid ejecting head, and the liquid ejecting apparatus.

A configuration obtained by replacing the configurations disclosed in the embodiments and modification examples described above or by changing the combination thereof, and a configuration obtained by replacing the configurations disclosed in the related art, embodiments, and modification examples or by changing the combination thereof may be embodied. The invention also includes such configurations.

What is claimed is:

1. A method of manufacturing a piezoelectric element having a piezoelectric layer and an electrode, the method comprising:
forming the electrode having at least lanthanum nickel preferentially aligned in (100) plane, on a surface thereof;
applying a precursor solution including at least Bi, Ba, Fe, and Ti onto the surface of the electrode; and
crystallizing the applied precursor solution to form the piezoelectric layer including a perovskite oxide preferentially aligned in (100) plane.

2. The method of manufacturing a piezoelectric element according to claim 1, wherein the forming of the piezoelectric layer includes first heating of the application film on the surface of the electrode at a temperature lower than a crystallization temperature of the perovskite oxide, and second heating of the application film on the surface of the electrode after the first heating at a temperature equal to or higher than the crystallization temperature.

3. The method of manufacturing a piezoelectric element according to claim 2, wherein the crystallization temperature is 400 to 450° C.

4. The method of manufacturing a piezoelectric element according to claim 2, wherein in the second heating, the application film on the surface of the electrode is heated equal to or higher than 450° C.

5. The method of manufacturing a piezoelectric element according to claim 2, wherein in the second heating, the application film on the surface of the electrode is heated equal to or higher than the crystallization temperature by an infrared lamp annealing device.

6. The method of manufacturing a piezoelectric element according to claim 1, wherein the precursor solution includes Mn.

7. The method of manufacturing a piezoelectric element according to claim 1, wherein a factor F*₍₁₀₀₎ of the piezoelectric layer is equal to or more than 0.89, where a reflection intensity from a (100) alignment plane acquired from an X-ray diffraction chart of the piezoelectric layer according to an X-ray diffraction wide angle method is A₍₁₀₀₎, a reflection intensity from a (110) alignment plane acquired from the X-ray diffraction chart is A₍₁₁₀₎, A₍₁₀₀₎/(A₍₁₀₀₎+A₍₁₀₀₎) is P*₍₁₀₀₎, a reflection intensity from the (100) alignment plane when crystals are not aligned is A₀₍₁₀₀₎, a reflection intensity from the (110) alignment plane when crystals are not aligned is A₀₍₁₀₀₎, A₀₍₁₀₀₎/(A₀₍₁₀₀₎+A₀₍₁₁₀₎) is P*₀₍₁₀₀₎, and (P*₍₁₀₀₎−P*₀₍₁₀₀₎)/(1−P*₀₍₁₀₀₎) is a factor F*₍₁₀₀₎.

8. A method of manufacturing a liquid ejecting head comprising: forming a piezoelectric element by the method of manufacturing a piezoelectric element according to claim 1.

9. A method of manufacturing a liquid ejecting head comprising: forming a piezoelectric element by the method of manufacturing a piezoelectric element according to claim 2.

10. A method of manufacturing a liquid ejecting head comprising: forming a piezoelectric element by the method of manufacturing a piezoelectric element according to claim 3.

11. A method of manufacturing a liquid ejecting head comprising: forming a piezoelectric element by the method of manufacturing a piezoelectric element according to claim 4.

12. A method of manufacturing a liquid ejecting head comprising: forming a piezoelectric element by the method of manufacturing a piezoelectric element according to claim 5.

13. A method of manufacturing a liquid ejecting head comprising: forming a piezoelectric element by the method of manufacturing a piezoelectric element according to claim 6.

14. A method of manufacturing a liquid ejecting head comprising: forming a piezoelectric element by the method of manufacturing a piezoelectric element according to claim 7.

15. A method of manufacturing a liquid ejecting apparatus comprising: forming a liquid ejecting head by the method of manufacturing a liquid ejecting head according to claim 8.

16. A method of manufacturing a liquid ejecting apparatus comprising: forming a liquid ejecting head by the method of manufacturing a liquid ejecting head according to claim 9.

17. A method of manufacturing a liquid ejecting apparatus comprising: forming a liquid ejecting head by the method of manufacturing a liquid ejecting head according to claim 10.

18. A method of manufacturing a liquid ejecting apparatus comprising: forming a liquid ejecting head by the method of manufacturing a liquid ejecting head according to claim 11.

19. A method of manufacturing a liquid ejecting apparatus comprising: forming a liquid ejecting head by the method of manufacturing a liquid ejecting head according to claim 12.

20. A method of manufacturing a liquid ejecting apparatus comprising: forming a liquid ejecting head by the method of manufacturing a liquid ejecting head according to claim 13.
